(19) United States
(12) Patent Application Publication
(10) Pub. No.: US 2023/0141029 A1
(43) Pub. Date: May 11, 2023

(54) DECODER FOR DECODING WEIGHT PARAMETERS OF A NEURAL NETWORK, ENCODER, METHODS AND ENCODED REPRESENTATION USING PROBABILITY ESTIMATION PARAMETERS

(71) Applicant: Fraunhofer-Gesellschaft zur Förderung der angewandten Forschung e.V., München (DE)

(72) Inventors: Paul HAASE, Berlin (DE); Karsten MÜLLER, Berlin (DE); Heiner KIRCHHOFFER, Berlin (DE); Heiko SCHWARZ, Berlin (DE); Detlev MARPE, Berlin (DE); Thomas WIEGAND, Berlin (DE)

(21) Appl. No.: 18/046,227

(22) Filed: Oct. 13, 2022

Related U.S. Application Data
(63) Continuation of application No. PCT/EP2021/059594, filed on Apr. 13, 2021.

(30) Foreign Application Priority Data
Apr. 14, 2020 (EP) 20169498.1

(51) Int. Cl. G06N 3/0455; G06F 18/211; G06F 18/21

(52) U.S. Cl. CPC G06N 3/0455; G06F 18/211; G06F 18/2193

(57) ABSTRACT

A decoder for decoding weight parameters of a neural network, wherein the decoder is configured to obtain a plurality of neural network parameters of the neural network on the basis of an encoded bitstream. Furthermore, the decoder is configured to decode the neural network parameters of the neural network using a context-dependent arithmetic decoding Moreover, the decoder is configured to obtain a probability estimate for a decoding of a bin of a number representation of a neural network parameter using one or more probability estimation parameters. In addition, the decoder is configured to use different probability estimation parameter values for a decoding of different neural network parameters and/or to use different probability estimation parameter values for a decoding of bins associated with different context models. Some embodiments are configured to use different probability estimation parameter values for a decoding of neural network parameters of different layers of the neural network.

### CROSS REFERENCE TO RELATED APPLICATIONS

This application is a continuation of copending International Application No. PCT/EP2021/059594, filed Apr. 13, 2021, which is incorporated herein by reference in its entirety, and additionally claims priority from European Application No. 20169498.1, filed Apr. 14, 2020, which is also incorporated herein by reference in its entirety.

### TECHNICAL FIELD

Embodiments according to the invention comprise an encoder for encoding weight parameters of a neural network, a decoder, methods and an encoded representation using probability estimation parameters.

### BACKGROUND OF THE INVENTION

In the following background information for a better understanding of the invention will be provided. However, it is to be noted, that the features, functionalities and details described in the background information may optionally be used in combination with any embodiments of the present invention (both individually and taken in combination).

In their most basic form, neural networks constitute, for example, a chain of affine transformations followed by an element-wise non-linear function. They may, for example, be represented as a directed acyclic graph, as depicted in FIG. 1.

FIG. 1 shows an example for a graph representation of a feed forward neural network. Specifically, this 2-layered neural network is a non-linear function which maps a 4-dimensional input vector into the real line.

For example, each node entails a particular value, which is forward propagated into the next node, for example, by multiplication with the respective weight value of the edge. All incoming values are then, for example, simply aggregated.

Mathematically, the neural network of FIG. 1 would, for example, calculate the output in the following manner:

$$o u t p u t = {L}_{2} \left({L}_{1} \left(i n p u t\right)\right)$$

where

$${L}_{i} \left(X\right) = {N}_{i} \left({B}_{i} \left(X\right)\right)$$

and where, for example, Bᵢ is the affine transformation of layer i and where, for example, Nᵢ is some non-linear function of layer i. A simple example for Bᵢ is a matrix multiplication of weight parameters (edge weights) Wᵢ associated with layer i with the input X:

$${B}_{i} \left(X\right) = {W}_{i} ∗ X$$

The operator _{*} shall denote matrix multiplication.

For example, so-called convolutional layers may also be used by casting them as matrix-matrix products as described, for example, in “cuDNN: Efficient Primitives for Deep Learning” (Sharan Chetlur, et al.; arXiv: 1410.0759, 2014). From now on, we will refer as inference the procedure of calculating the output from a given input. Also, we will call intermediate results as hidden layers or hidden activation values, which constitute a linear transformation + element-wise non-linearity, e.g. such as the calculation of the first dot product + non-linearity above.

In the following, a bias and batch norm for a neural network is discussed. A more sophisticated variant of affine transformation of a neural network layers includes a so-called bias- and batch-norm operation, for example, as follows:

$$B N \left(X\right) = \frac{W ∗ X + b - μ}{\sqrt{{σ}^{2} + ∈}} ⋅ γ + β$$

where b is denoted bias and where µ , σ² , y, and β are denoted batch norm parameters. W is a weight matrix, for example, with dimensions n × k and X is the input matrix, for example, with dimensions k × m. Bias b and batch norm parameters µ , σ², y, and β are, for example, transposed vectors, for example, of length n. Operator _{*} denotes a matrix multiplication. Note that, for example, all other operations (summation, multiplication, division) on a matrix with a vector are element-wise operations on the columns of the matrix. For example, X . γ means that each column of X is multiplied element-wise with y.

∈ is, for example, a small scalar number (like e.g. 0.001) required (or useful) to avoid divisions by 0. However, it may also be 0. In the case b = 0, Equation 1 refers to a batch-norm layer. In contrast, if ∈ and all vector elements of µ and β are set to zero and all elements of y and σ² are set to 1, a layer without batch norm (bias only) is adressed.

Usually, neural networks contain, for example, millions of parameters, and may thus, for example, require hundreds of MByte for their representation. Consequently, they require high computational resources in order to be executed since their inference procedure involves computations of many dot product operations, for example, between large matrices. Hence, it is of high importance to reduce the complexity of performing these dot products.

As another consequence, encoding and/or decoding of neural network parameters is challenging. For example, in order to transmit the millions of parameters of a neural network large transmission rates may be required.

Hence, there is a need for an improved concept for encoding and/or decoding neural network parameters providing a good compromise between compression, complexity and computational costs.

### SUMMARY

An embodiment may have a decoder for decoding weight parameters of a neural network, wherein the decoder is configured to obtain a plurality of neural network parameters of the neural network on the basis of an encoded bitstream; wherein the decoder is configured to decode the neural network parameters of the neural network using a context-dependent arithmetic decoding; wherein the decoder is configured to obtain a probability estimate for a decoding of a bin of a number representation of a neural network parameter using one or more probability estimation parameters; wherein the decoder is configured to use different probability estimation parameter values for a decoding of different neural network parameters and/or to use different probability estimation parameter values for a decoding of bins associated with different context models.

Another embodiment may have a decoder for decoding weight parameters of a neural network, wherein the decoder is configured to obtain a plurality of neural network parameters of the neural network on the basis of an encoded bitstream; wherein the decoder is configured to decode the neural network parameters of the neural network using a context-dependent arithmetic decoding; wherein the decoder is configured to obtain a probability estimate for a decoding of a bin of a number representation of a neural network parameter using one or more probability estimation parameters; wherein the decoder is configured to use different probability estimation parameter values for a decoding of neural network parameters associated with different layers of the neural network.

Another embodiment may have an encoder for encoding weight parameters of a neural network, wherein the encoder is configured to obtain a plurality of neural network parameters of the neural network; wherein the encoder is configured to encode the neural network parameters of the neural network using a context-dependent arithmetic coding; wherein the encoder is configured to obtain a probability estimate for an encoding of a bin of a number representation of a neural network parameter using one or more probability estimation parameters; wherein the encoder is configured to use different probability estimation parameter values for an encoding of different neural network parameters and/or to use different probability estimation parameter values for an encoding of bins associated with different context models.

Another embodiment may have an encoder for encoding weight parameters of a neural network, wherein the encoder is configured to obtain a plurality of neural network parameters of the neural network; wherein the encoder is configured to encode the neural network parameters of the neural network using a context-dependent arithmetic coding; wherein the encoder is configured to obtain a probability estimate for an encoding of a bin of a number representation of a neural network parameter using one or more probability estimation parameters; wherein the encoder is configured to use different probability estimation parameter values for an encoding of neural network parameters associated with different layers of the neural network.

Another embodiment may have a method for decoding weight parameters of a neural network, wherein the method has obtaining a plurality of neural network parameters of the neural network on the basis of an encoded bitstream; wherein the method has decoding the neural network parameters of the neural network using a context-dependent arithmetic decoding; wherein the method has obtaining a probability estimate for an decoding of a bin of a number representation of a neural network parameter using one or more probability estimation parameters; wherein the method has using different probability estimation parameter values for a decoding of different neural network parameters and/or using different probability estimation parameter values for a decoding of bins associated with different context models.

Still another embodiment may have a method for decoding weight parameters of a neural network, wherein the method has obtaining a plurality of neural network parameters of the neural network on the basis of an encoded bitstream; wherein the method has decoding the neural network parameters of the neural network using a context-dependent arithmetic decoding; wherein the method has obtaining a probability estimate for an decoding of a bin of a number representation of a neural network parameter using one or more probability estimation parameters; wherein the method has using different probability estimation parameter values for a decoding of neural network parameters associated with different layers of the neural network.

Another embodiment may have a method for encoding weight parameters of a neural network, wherein the method has obtaining a plurality of neural network parameters of the neural network; wherein the method has encoding the neural network parameters of the neural network using a context-dependent arithmetic coding; wherein the method has obtaining a probability estimate for an encoding of a bin of a number representation of a neural network parameter using one or more probability estimation parameters; wherein the method has using different probability estimation parameter values for an encoding of different neural network parameters and/or using different probability estimation parameter values for an encoding of bins associated with different context models.

Another embodiment may have a method for encoding weight parameters of a neural network, wherein the method has obtaining a plurality of neural network parameters of the neural network; wherein the method has encoding the neural network parameters of the neural network using a context-dependent arithmetic coding; wherein the method has obtaining a probability estimate for an encoding of a bin of a number representation of a neural network parameter using one or more probability estimation parameters; wherein the method has using different probability estimation parameter values for an encoding of neural network parameters associated with different layers of the neural network.

Another embodiment may have a computer program for performing the inventive methods for decoding and encoding as mentioned above when the computer program runs on a computer.

According to another embodiment, an encoded representation of weight parameters of a neural network may have: a plurality of encoded weight parameters of the neural network; and an encoded representation of one or more probability estimation parameters determining characteristics of a probability estimation for an adaptation of a context of an arithmetic decoding of the encoded weight parameters.

Embodiments according to the invention comprise a decoder for decoding weight parameters of a neural network, wherein the decoder is configured to obtain a plurality of neural network parameters, e.g., at least one of entries Wᵢ of matrix W, b, µ, σ², σ, _{Y}, and/or β, of the neural network on the basis of an encoded bitstream. Furthermore, the decoder is configured to decode the neural network parameters, e.g., entries Wᵢ of matrix W, or b, or µ, or σ², or σ, or _{Y},or β,of the neural network, e.g., a quantized version of the neural network parameters, using a context-dependent arithmetic decoding, e.g., using a context-adaptive binary arithmetic decoding (CABAC). Optionally, probabilities of bin values may be determined for different contexts, wherein, for example, each bin is associated with a context. Moreover, the decoder is configured to obtain a probability estimate, e.g. P(t) or pₖ,, which may, for example, be associated with a context, for a, e.g. arithmetic, decoding of a bin of a number representation of a neural network parameter, e.g. on the basis of one or more previously decoded neural network parameters or bins thereof, using one or more probability estimation parameters, e.g., probability estimator parameters, e.g. N ,

$${a}_{i}^{k} , {b}_{i}^{k} {a}_{k} , {d}_{i}^{k} , A , {m}_{i}^{k} , {n}_{i}^{k} , s {h}_{i}^{k} , i n i t V a {l}_{i}^{k} .$$

In addition, the decoder is configured to use different probability estimation parameter values for a decoding of different neural network parameters and/or to use different probability estimation parameter values for a decoding of bins associated with different context models, e.g. cₖ.

Further embodiments according to the invention comprise a decoder for decoding weight parameters of a neural network, wherein the decoder is configured to obtain a plurality of neural network parameters, e.g., at least one of entries Wᵢ of matrix W, b, µ, σ², σ, _{Y},and/or β, of the neural network on the basis of an encoded bitstream. Furthermore, the decoder is configured to decode the neural network parameters, e.g., entries Wᵢ of matrix W, or b, or µ, or σ², or σ, or _{Y},or βof the neural network, e.g., a quantized version of the neural network parameters, using a context-dependent arithmetic decoding, e.g., using a context-adaptive binary arithmetic decoding (CABAC). Optionally, probabilities of bin values may be determined for different contexts, wherein, for example, each bin is associated with a context. Moreover, the decoder is configured to obtain a probability estimate, e.g. P(t) or pₖ, which may, for example, be associated with a context, for a, e.g. arithmetic, decoding of a bin of a number representation of a neural network parameter, e.g. on the basis of one or more previously decoded neural network parameters or bins thereof, using one or more probability estimation parameters, e.g., probability estimator parameters, e.g. N ,

$${a}_{i}^{k} , {b}_{i}^{k} , {a}_{k} , {a}_{i}^{k} , A , {m}_{i}^{k} , {n}_{i}^{k} , s {h}_{i}^{k} , i n i t V a {l}_{i}^{k} .$$

In addition, the decoder is configured to use different probability estimation parameter values for a decoding of neural network parameters associated with different layers of the neural network.

Embodiments according to the invention comprise an encoder for encoding weight parameters of a neural network, wherein the encoder is configured to obtain a plurality of neural network parameters, e.g., at least one of entries wᵢ of matrix W, b, µ, σ², σ, _{Y}, and/or β, of the neural network. Furthermore, the encoder is configured to encode the neural network parameters, e.g., entries wᵢ of matrix W, or b, or µ, or σ², or σ, or _{Y},or β, of the neural network, e.g., a quantized version thereof, using a context-dependent arithmetic coding, e.g., using a context-adaptive binary arithmetic coding (CABAC). Optionally, probabilities of bin values may be determined for different contexts, wherein, for example, each bin is associated with a context. In addition, the encoder is configured to obtain a probability estimate, e.g. P(t) or pₖ, which may, for example, be associated with a context, for an, optionally arithmetic, encoding of a bin of a number representation of a neural network parameter, e.g. on the basis of one or more previously encoded neural network parameters or bins thereof, using one or more probability estimation parameters, e.g., probability estimator parameters, e.g. N ,

$${a}_{i}^{k} , {b}_{i}^{k} , {a}_{k} , {d}_{i}^{k} , A , {m}_{i}^{k} , {n}_{i}^{k} , s {h}_{i}^{k} , i n i t V a {l}_{i}^{k} .$$

Moreover, the encoder is configured to use different probability estimation parameter values for an encoding of different neural network parameters and/or to use different probability estimation parameter values for an encoding of bins associated with different context models, e.g. cₖ.

Further embodiments according to the invention comprise an encoder for encoding weight parameters of a neural network, wherein the encoder is configured to obtain a plurality of neural network parameters, e.g., entries wᵢ of matrix W, b, µ, σ², σ, _{Y},and/or β, of the neural network. Furthermore, the encoder is configured to encode the neural network parameters, e.g., entries wᵢ of matrix W, or b, or µ, or σ², or σ, or _{Y},or β,of the neural network, e.g., a quantized version thereof, using a context-dependent arithmetic coding, e.g., using a context-adaptive binary arithmetic coding (CABAC). Optionally, probabilities of bin values may be determined for different contexts, wherein, for example, each bin is associated with a context. Moreover, the encoder is configured to obtain a probability estimate, e.g. P(t) or pₖ,, which may, for example, be associated with a context, for an, optionally arithmetic, encoding of a bin of a number representation of a neural network parameter, e.g. on the basis of one or more previously encoded neural network parameters or bins thereof, using one or more probability estimation parameters, e.g., probability estimator parameters, e.g. N ,

$${a}_{i}^{k} , {b}_{i}^{k} , {a}_{k} , {d}_{i}^{k} , A , {m}_{i}^{k} , {n}_{i}^{k} , s {h}_{i}^{k} , i n i t V a {l}_{i}^{k} .$$

In addition, the encoder is configured to use different probability estimation parameter values for an encoding of neural network parameters associated with different layers of the neural network.

Embodiments according to the invention comprise a method for decoding weight parameters of a neural network, wherein the method comprises obtaining a plurality of neural network parameters, e.g., at least one of entries wᵢ of matrix W, b, µ, σ², σ, _{Y}, and/or β, of the neural network on the basis of an encoded bitstream, wherein the method comprises decoding the neural network parameters, e.g., entries wᵢ of matrix W, or b, or µ, or σ², or σ, or _{Y},or β, of the neural network, e.g., a quantized version of the neural network parameters, using a context-dependent arithmetic decoding, e.g., using a context-adaptive binary arithmetic decoding (CABAC). Optionally, probabilities of bin values are determined for different contexts, wherein, for example, each bin may be associated with a context. Furthermore, the method comprises obtaining a probability estimate, e.g. P(t) or pₖ, which may, for example, be associated with a context, for an, e.g. arithmetic, decoding of a bin of a number representation of a neural network parameter, e.g. on the basis of one or more previously decoded neural network parameters or bins thereof, using one or more probability estimation parameters, e.g., probability estimator parameters, e.g.

$$N , {a}_{i}^{k} , {b}_{i}^{k} , {a}_{k} , {d}_{i}^{k} , A , {m}_{i}^{k} , {n}_{i}^{k} ,$$

$$s {h}_{i}^{k} , i n i t V a {l}_{i}^{k} .$$

In addition, the method comprises using different probability estimation parameter values for a decoding of different neural network parameters and/or using different probability estimation parameter values for a decoding of bins associated with different context models, e.g. cₖ.

Further embodiments according to the invention comprise a method for decoding weight parameters of a neural network, wherein the method comprises obtaining a plurality of neural network parameters, e.g., at least one of entries wᵢ of matrix W, b, µ, σ², σ, _{Y},and/or β, of the neural network on the basis of an encoded bitstream. Furthermore, the method comprises decoding the neural network parameters, e.g., entries wᵢ of matrix W, or b, or µ, or σ², or σ, or _{Y},or β,of the neural network, e.g., a quantized version of the neural network parameters, using a context-dependent arithmetic decoding, e.g., using a context-adaptive binary arithmetic decoding (CABAC). Optionally, probabilities of bin values may be determined for different contexts, wherein, for example, each bin is associated with a context. Moreover, the method comprises obtaining a probability estimate, e.g. P(t) or pₖ, which may, for example, be associated with a context, for an, e.g. arithmetic, decoding of a bin of a number representation of a neural network parameter, e.g. on the basis of one or more previously decoded neural network parameters or bins thereof, using one or more probability estimation parameters, e.g., probability estimator parameters, e.g. N ,

$${a}_{i}^{k} , {b}_{i}^{k} , {a}_{k} , {d}_{i}^{k} , A , {m}_{i}^{k} , {n}_{i}^{k} , s {h}_{i}^{k} , i n i t V a {l}_{i}^{k} .$$

In addition, the method comprises using different probability estimation parameter values for a decoding of neural network parameters associated with different layers of the neural network.

Embodiments according to the invention comprise a method for encoding weight parameters of a neural network, wherein the method comprises obtaining a plurality of neural network parameters, e.g., at least one of entries wᵢ of matrix W, b, µ, σ², σ, _{Y}, and/or β, of the neural network. Furthermore, the method comprises encoding the neural network parameters, e.g., entries wᵢ of matrix W, or b, or µ, or σ², or σ, or _{Y},or β, of the neural network, e.g., a quantized version of the neural network parameters, using a context-dependent arithmetic coding, e.g., using a context-adaptive binary arithmetic coding (CABAC). Optionally, probabilities of bin values may be determined for different contexts, wherein, for example, each bin may be associated with a context. Moreover, the method comprises obtaining a probability estimate, e.g. P(t) or pₖ, which may, for example, be associated with a context, for a, e.g. arithmetic, encoding of a bin of a number representation of a neural network parameter, e.g. on the basis of one or more previously encoded neural network parameters or bins thereof, using one or more probability estimation parameters, e.g., probability estimator parameters, e.g. N,

$${a}_{i}^{k} , {b}_{i}^{k} , {a}_{k} , {d}_{i}^{k} , A , {m}_{i}^{k} , {n}_{i}^{k} , s {h}_{i}^{k} , i n i t V a {l}_{i}^{k} .$$

In addition, the method comprises using different probability estimation parameter values for an encoding of different neural network parameters and/or using different probability estimation parameter values for an encoding of bins associated with different context models, e.g. cₖ.

Further embodiments according to the invention comprise a method for encoding weight parameters of a neural network, wherein the method comprises obtaining a plurality of neural network parameters, e.g., at least one of entries wᵢ of matrix W, b, µ, σ², σ, _{Y},and/or β, of the neural network. Furthermore, the method comprises encoding the neural network parameters, e.g., entries wᵢ of matrix W, or b, or µ, or σ², or σ, or _{Y}, or β, of the neural network, e.g., a quantized version of the neural network parameters, using a context-dependent arithmetic coding, e.g., using a context-adaptive binary arithmetic coding (CABAC). Optionally, probabilities of bin values may be determined for different contexts, wherein, for example, each bin may be associated with a context. Moreover, the method comprises obtaining a probability estimate, e.g. P(t) or pₖ, which may, for example, be associated with a context, for an, e.g. arithmetic, encoding of a bin of a number representation of a neural network parameter, e.g. on the basis of one or more previously encoded neural network parameters or bins thereof, using one or more probability estimation parameters, e.g., probability estimator parameters, e.g. N,

$${a}_{i}^{k} , {b}_{i}^{k} , {a}_{k} , {d}_{i}^{k} , A , {m}_{i}^{k} , {n}_{i}^{k} , s {h}_{i}^{k} , i n i t V a {l}_{i}^{k} .$$

In addition, the method comprises using different probability estimation parameter values for an encoding of neural network parameters associated with different layers of the neural network.

Embodiments according to the invention comprise a computer program for performing a method according to the invention when the computer program runs on a computer.

Embodiments according to the invention comprise an encoded representation of weight parameters of a neural network, comprising a plurality of encoded weight parameters of the neural network and an encoded representation of one or more probability estimation parameters determining characteristics of a probability estimation for an adaptation of a context of an arithmetic decoding of the encoded weight parameters.

For a better understanding of the main idea of embodiments of the invention, in the following, further optional aspects of neural network parameter encoding and respectively decoding according to the invention are disclosed. Firstly, inter alia, an efficient representation of parameters according to embodiments is disclosed. Explained details in the following are optional.

The parameters W, b, µ, σ², γ, and β may be collectively denoted parameters of a layer or layer parameters. One or more of these parameters may be examples for the neural network parameters, as explained before. They usually need to be signaled in a bitstream (e.g. in an encoded video representation, for example, if the neural network is used in a video decoder). For example, they could be represented as 32 bit floating point numbers or they could, for example, be quantized to an integer representation, also denoted as quantization indices. Note that ∈ is usually not signaled in the bitstream.

For example, a particularly efficient approach for encoding such parameters employs a uniform reconstruction quantizer (URQ) where, for example, each value is represented as integer multiple of a so-called quantization step size value. The corresponding floating point number can, for example, be reconstructed by multiplying the integer with the quantization step size, which is usually (but not necessarily) a single floating point number. However, for example, efficient implementations for neural network inference (that is, calculating the output of the neural network for an input) employ integer operations whenever possible. Therefore, it may be undesirable to use parameters to be reconstructed to a floating point representation.

In another efficient approach for encoding the parameters, a set of quantizers is applied where each value is, for example, represented as integer multiple of a quantization step size value. Usually, for example, each quantizer in the set employs a disjoint set of integer multiples of the quantization step size parameter as applicable reconstruction values, but two or more quantizers may share one or more reconstruction values. The applied quantizer depends, for example, on the values of previous quantization indices in coding order. The corresponding floating point number can, for example, be reconstructed by multiplying the integer with the quantization step size, which is usually, for example, a floating point number which depends on the chosen quantizer. An example for such a quantizer design is trellis coded quantization (TCQ), also denoted as dependent quantization (DQ).

In an embodiment a set of two quantizers is used. The first quantizer employs, for example, all even multiples of the quantization step size including zero, and the second quantizer employs all the even multiples of the quantization step size including zero.

Secondly, inter alia, Entropy Coding and Probability Estimation according to embodiments is disclosed. Explained details in the following are optional and especially combinable with the features explained above, concerning efficient representation of parameters.

The quantization indices that are output, for example, by the quantization method, e.g. as explained above, may then be entropy coded using a suitable entropy coding method.

A particularly suitable entropy coding method for encoding such quantization indices is Context-based Adaptive Binary Arithmetic Coding, also denoted as CABAC. For this, each quantization index is, for example, decomposed into a sequence of binary decisions, so-called bins. Usually, for example, each bin is associated with a probability model, also denoted as context model, which models the statistics of the associated bins, for example, using a probability estimation method.

A probability estimator is an apparatus, that models the probability P(t) for a bin being equal to x, where x ∈ {0,1} , for example, based on already coded bins associated with the probability estimator. P(t) may be an example for the probability estimate.

Next, a for example typical, estimator design is explained. Details of the estimator design are optional features of embodiments according to the invention, and are especially combinable with embodiments comprising the above explained features.

First, a typical estimator design, that is applied in neural network compression, is described.

For example, for each context model cₖ, one or more state variables

$${s}_{1}^{k} , … , {s}_{N}^{k}$$

are maintained with N ≥ 1. Each state variable

$${s}_{i}^{k}$$

is implemented, for example, as signed integer value and represents, for example, a probability value

$$P \left({s}_{i}^{k} , i , k\right) = {p}_{i}^{k} .$$

The probability estimate pₖ of a context model cₖ shall be defined, for example, as weighted sum of the probability values

$${p}_{i}^{k}$$

of all state variables of the context model.

State variables shall advantageously but not necessarily have the following properties:
1.
$$\text{If} {s}_{i}^{k} = 0 , \text{then} {p}_{i}^{k} = 0.5.$$
2. Larger values for
$${s}_{i}^{k}$$
correspond to larger
$${p}_{i}^{k} .$$
3.
$$P \left(- {s}_{i}^{k} , i , k\right) = 1 - P \left({s}_{i}^{k} , i , k\right) .$$

Consequently, negative state variables may, for example, correspond to

$${p}_{i}^{k} < 0.5.$$

In general, it is possible to specify different functions P(·) for each state variable of each context model.

Next, an exemplary configuration for associating state variables with probability values is explained. details of the state association are optional features of embodiments according to the invention, and are especially combinable with embodiments comprising the above explained features.

There exist many useful ways of associating state variables with probability values, i.e., of implementing P(·). For example, a state representation that is used in neural network compression can be achieved with the following equation:

$$P \left(x , i , k\right) = \left\{\begin{matrix}0.5 ⋅ {α}^{\left⌊x ⋅ {β}_{i}^{k}\right⌋} , i f x \geq 0 , \\ 1 - 0.5 ⋅ {α}^{\left⌊- x ⋅ {β}_{i}^{k}\right⌋} , e l s e .\end{matrix}\right)$$

$${β}_{i}^{k}$$

is a weighting factor. α is a parameter with 0 < α < 1.

To achieve, for example, a configuration comparable to the one used in the current draft of MPEG-7 part 17 standard for compression of neural networks for multimedia content description and analysis, which uses two states

$$\left(N = 2 , {s}_{1}^{k} , {s}_{2}^{k}\right) ,$$

set α ≈0.99894079 and

$${β}_{1}^{k}$$

= 16 and

$${β}_{2}^{k}$$

= 1 for all k.

This exemplary configuration shall give some insight about how state variables could be defined. In general, it is not necessary to define P(·) because it is not directly used, as will be seen in the following. Instead, it often results from the actual implementation of the individual parts.

Next, an initialization of state variables is explained. details of the initialization are optional features of embodiments according to the invention, and are especially combinable with embodiments comprising the above explained features.

Before encoding or decoding the first symbol with a context model, all state variables are optionally initialized with same values, denoted as

$$i n i t V a {l}_{i}^{k} ,$$

that may, for example, be optimized to the compression application.

Next, a derivation of a probability estimate from state variables is explained. details of the derivation are optional features of embodiments according to the invention, and are especially combinable with embodiments comprising the above explained features.

For encoding or decoding of a symbol, a probability estimate is derived from the state variables of a context model. Three alternative approaches are presented in the following as examples. Approach 1 yields more accurate results than approach 2 and approach 3, but also has a higher computational complexity.

### Approach 1 Example

This approach consists of two steps. Firstly, each state variable

$${s}_{i}^{k}$$

of a context model is converted into a probability value

$${p}_{i}^{k} .$$

Secondly, the probability estimate pₖ is derived as weighted sum of the probability values

$${p}_{i}^{k} ⋅$$

### Step 1

A lookup table LUT1 is employed for converting a state variable

$${s}_{i}^{k}$$

into the corresponding probability value

$${p}_{i}^{k}$$

, for example according to Eq. (1).

$${p}_{i}^{k} = \left\{\begin{matrix}L U T 1 \left[\left⌊{s}_{i}^{k} ⋅ {α}_{i}^{k}\right⌋\right] , & i f {s}_{i}^{k} \geq 0. \\ 1 - L U T 1 \left[\left⌊- {s}_{i}^{k} ⋅ {α}_{i}^{k}\right⌋\right] , & e l s e .\end{matrix}\right)$$

LUT1 is a lookup table containing probability values.

$${a}_{i}^{k}$$

is a weighting factor that adapts

$${s}_{i}^{k}$$

to the size of LUT1.

### Step 2

The probability estimate pₖ is derived from the probability values pf, for example according to:

$${p}_{k} = {\sum }_{i = 1}^{N} {p}_{i}^{k} ⋅ {b}_{i}^{k}$$

$${b}_{i}^{k}$$

is a weighting factor that controls the influence of the individual state variables.

### Approach 2 Example

An alternative approach for deriving the probability estimate from the state variables is presented in the following. It yields less accurate results and has a lower computational complexity. Firstly, a weighted sum sₖ of the state variables is derived, for example, according to:

$${s}_{k} = {\sum }_{i = 1}^{N} \left⌊{s}_{i}^{k} ⋅ {d}_{i}^{k}\right⌋$$

$${d}_{i}^{k}$$

is a weighting factor that controls the influence of each state variable.

Secondly, the probability estimate pₖ is derived from the weighted sum of state variables sₖ, for example according to:

$${p}_{k} = \left\{\begin{matrix}L U T 2 \left[\left⌊{s}_{k} ⋅ {a}_{k}\right⌋\right] , i f {s}_{k} \geq 0. \\ 1 - L U T 2 \left[\left⌊- {s}_{k} ⋅ {a}_{k}\right⌋\right] , e l s e .\end{matrix}\right)$$

LUT2 is a lookup table containing probability estimates, aₖ is a weighting factor that adapts sₖ to the size of LUT2.

### Approach 3 Example

A further alternative approach for deriving the probability estimate from the state variables is presented in the following. Firstly, the weighted sum sₖ of the state variables is derived, for example, as in approach 2. Secondly, the probability estimate pₖ is derived from the weighted sum of state variables sₖ, for example according to:

$${p}_{k} = \left\{\begin{matrix}L U T 2 \left[\left⌊{s}_{k} ⋅ {a}_{k}\right⌋\right] , i f {s}_{k} \geq 0. \\ 1 - L U T 2 \left[- \left⌊{s}_{k} ⋅ {a}_{k}\right⌋\right] , e l s e .\end{matrix}\right)$$

LUT2 is a lookup table containing probability estimates.

### Approach 4 Example

A further approach uses a linear relation between the state values and the probability P(x, i, k). The derivation of the probability estimate is, for example, using the approach of equation (2). An example of approach 4 is the probability estimation scheme used in the current draft of Versatile Video Coding (VVC).

To achieve, for example, a configuration used in the current draft of MPEG-7 part 17 standard for compression of neural networks for multimedia content description and analysis, the method of approach 3 is used, for example, with

$${d}_{1}^{k} = 16 , {d}_{2}^{k} = 1$$

and aₖ = 2⁻⁷ for all k. The look-up table containing the probability estimates is, for example:

LUT2 = {0.5000, 0.4087,0.3568, 0.3116, 0.2721, 0.2375,0.2074, 0.1811, 0.1581, 0.1381,0.1206, 0.1053, 0.0919, 0.0803, 0.0701, 0.0612, 0.0534, 0.0466,0.0407, 0.0356, 0.0310, 0.0271, 0.0237, 0.0207, 0.0180, 0.0158,0.0138, 0.0120, 0.0105, 0.0092, 0.0080, 0.0070}

Next, an update of state variables is explained. details of the update are optional features of embodiments according to the invention, and are especially combinable with embodiments comprising the above explained features.

After the encoding or decoding of a symbol, one or more state variables of a context model may be updated in order to track the statistical behavior of the symbol sequence.

The update is, for example, carried out as follows:

$${s}_{i}^{k} = \left\{\begin{matrix}{s}_{i}^{k} + \left⌊A \left[z + \left⌊{s}_{i}^{k} ⋅ {m}_{i}^{k}\right⌋\right] ⋅ {n}_{i}^{k}\right⌋ , I f s y m b o l t o b e e n c o d e d i s 1. \\ {s}_{i}^{k} - \left⌊A \left[z + \left⌊- {s}_{i}^{k} ⋅ {m}_{i}^{k}\right⌋\right] ⋅ {n}_{i}^{k}\right⌋ , I f s y m b o l t o b e e n c o d e d i s 0.\end{matrix}\right)$$

A is a lookup table storing, for example, integer values.

$${m}_{i}^{k}$$

and

$${n}_{i}^{k}$$

are weighting factors that control, for example, the update ‘agility’. The factors

$${n}_{i}^{k}$$

can be written, for example, according to

$${n}_{i}^{k} = {2}^{- s {h}_{i}^{k} + 4} , \text{where} s {h}_{i}^{k}$$

also denoted as adaptation parameter. z is an offset that ensures, for example, that look table A is accessed only with non-negative values.

The values in lookup table A can, for example, be chosen so that

$${s}_{i}^{k}$$

stays in a particular given interval. Usually, the values of look-up A approximate, for example, an update function. Alternatively, it is, for example, also possible to simply use the related update function for the state updates.

For example, the estimation method of VVC, following approach 4, applies update functions for the state update and uses bit shifts, which, for example, determine the ‘agility’ of the update. This corresponds, for example, to the adaptation parameters described above. Embodiments of the invention (see below, for example as explained according to the main idea of embodiments) can be applied to those in the same manner.

To achieve, for example, a configuration used in the current draft of MPEG-7 part 17 standard for compression of neural networks for multimedia content description and analysis, the parameters are chosen, for example, such that

$${m}_{1}^{k} = {2}^{- 3} , {m}_{2}^{k} = {2}^{- 7}$$

and

$${n}_{1}^{k} = {2}^{- 1} , {n}_{2}^{k} = 1 ,$$

for all k, and z = 16. The look-up table A is, for example: A = {157, 143, 129, 115, 101, 87, 73, 59, 45, 35, 29, 23, 17, 13, 9, 5, 4, 4, 4, 4, 4, 4, 4, 4, 4, 4, 4, 4, 4, 4, 4, 0 }.

Before encoding a symbol,

$${s}_{1}^{k}$$

shall, for example, be initialized with a value from the interval [-127,127] and

$${s}_{2}^{k}$$

shall be initialized, for example, with a value from the interval [-2047, 2047]. Consequently,

$${s}_{1}^{k}$$

can, for example, be implemented with an 8 bit signed integer value and

$${s}_{2}^{k}$$

can, for example, be implemented with a 12 bit signed integer.

As explained with the examples above, probability estimators have several parameters, denoted as probability estimator parameters or estimator parameters (or also as probability estimation parameters), that affect the probability estimates, e.g. the adaptation rate. Usually, those estimator parameters are, for example, chosen globally, depending on the application scenario, e.g. encoding of neural network parameters. Thus, for example, in neural network encoding, each neural network parameter applies the same set of estimator parameters. But, it has been found by the inventors that the compression efficiency can be improved by selecting optimized estimator parameters for a current neural network parameter. So, according to an aspect, the basic idea is to select suitable estimator parameters out of a set of parameters, which are then signaled to the decoder.

In other words, embodiments according to the invention (e.g. as defined by the independent claims) are based on the idea to use different probability estimation parameters values for decoding and respectively encoding of neural network parameters or entities, e.g. bins associated with different contexts, associated with neural network parameters. Instead of using one fixed instance out of a base set of probability estimation parameters or probability parameter estimation values, an adapted or for example even optimal, individual choice of probability estimation parameters values may be performed. Selection of probability estimation values may be performed based on any suitable criterion, e.g. a priori known, characteristics of certain neural network parameters, stochastic features of context models of certain neural network parameters, or of bins of neural network parameters respectively. For example, it has been recognized that different neural network parameters may comprise different correlation characteristics, and that a adaptation of the probability estimation parameters to these different correlation characteristics may result in an improved coding efficiency. For example, depending on a functionality implemented by a neural network, a correlation strength between adjacent branches or edges of the neural network (neural network parameters) may differ. Also, an extension of the correlation between the edges (or branches) of the neural network may vary. According to an aspect of the present invention, the probability estimation parameter values may by adapted to the correlation characteristics (correlation strength/extension of the correlation) of the neural network (e.g. in a dynamic manner, e.g. even between an encoding of different neural network parameters of a single neural net), thus resulting in a particularly efficient encoding. As another example, it has been recognized that the correlation characteristics of neural network parameters associated with different layers of the neural network differ substantially in some cases. For example, if different layers of the neural network reflect convolutions of different sizes (or widths), this can be accomplished by using different probability estimation parameter values for the encoding or decoding of neural network parameters of different neural network layers, resulting in an improved coding efficiency.

To conclude, it has been found that a usage of different probability estimation parameters when encoding or decoding different neural network parameters or when encoding or decoding bins associated with different context models provides for an improved tradeoff between coding efficiency, complexity and resource usage. For example, it has been recognized that an overhead which may be used for a signaling (or even for a dynamic signaling) of the actually used probability estimation parameter values may be over-compensated by an increase in coding efficiency.

A second aspect according to embodiments of the invention is that encoding and/or decoding of the probability estimation parameters may comprise similar or even equal steps as the encoding and/or decoding of neural network parameters.

The inventors recognized that the encoding/decoding performance can be improved if the probability estimation parameters, e.g. all parameters related to the probability estimator and/or context model are chosen adaptively. The probability estimator parameters may be encoded/decoded using analogous steps as the neural network parameters. For example, the probability estimation parameters, or an integer index q representing the probability parameter may be encoded/decoded using a sequence of bins, e.g. bins greaterThan_0, greaterThan_1, ..., and context models analogously to the neural network parameters.

In other words, and vice versa for a decoder, a decoder according to embodiments of the invention may obtain an encoded bitstream, the bitstream comprising neural network parameters. The neural network parameters may be encoded in the bitstream as a sequence of bins. These bins may be decoded using context-dependent arithmetic decoding, for example the same context dependent arithmetic coding method used to encode the bins representing neural network parameters to the bitstream. Therefore, the decoder is configured to obtain a probability estimate using a probability estimator comprising one or more probability estimation parameters, for example at least one of the beforementioned probability estimator parameters e.g. at least one of

$$N , {a}_{i}^{k} , {b}_{i}^{k} , {a}_{k} , {d}_{i}^{k} , A , {m}_{i}^{k} , {n}_{i}^{k} , s {h}_{i}^{k} , i n i t V a {l}_{i}^{k} .$$

The decoder may then use different probability estimation parameter values for a decoding of different neural network parameters and/or different probability estimation parameter values for a decoding of bins associated with different context models, e.g. cₖ. Furthermore, the decoder may use different probability estimation parameter values for a decoding of neural network parameters associated with different layers of the neural network. By adapting the probability estimation parameter values according to certain characteristics of the neural network parameters, e.g. the layer or the context model of their bins decoding and encoding efficiency may be improved.

In other words, according to an aspect, the parameters, i.e.

$$N , {a}_{i}^{k} , {b}_{i}^{k} , {a}_{k} , {d}_{i}^{k} , A , {m}_{i}^{k} , {n}_{i}^{k} ,$$

$$s {h}_{i}^{k} , i n i t V a {l}_{i}^{k}$$

and/or any other parameter related to the probability estimator, e.g. context model may be collectively denoted as probability estimator parameters or estimator parameters (or probability estimation parameters).

Usually, for example, for each estimator parameter one fixed instance out of a base set of probability estimator parameters is chosen for the entire network. The values of the base set may also be N-tuples of estimator parameters, according to the number of applied states N. According to an aspect of the invention, the probability estimation, and thus the compression efficiency, can, for example, be improved, if the parameters are chosen individually for each parameter or a subset of parameters of a layer (i.e. W, b, µ, σ², γ, and β) and/or context model cₖ.

The estimator parameter to be used is, for example, determined among the parameters of a set of parameters, which can, for example, be the base set or any subset of the base set. Each parameter of the set may, for example, be associated with an integer index q. For example, one parameter of the set may be denoted as default parameter. Usually the default parameter is, for example, associated with an integer index equal to zero. The index associated with the chosen estimator parameter is then, for example, signaled to the decoder.

According to embodiments of the invention the decoder is configured to choose one or more probability estimation parameters from a base set or from a true subset of the base set. Optionally, the base set may comprise a plurality of useable parameter values associated with one or more probability estimation parameters, or wherein the base set may comprise a plurality of tuples of useable parameter values associated with a plurality of probability estimation parameters, e.g. a list of useable pairs

$$\left(s {h}_{1}^{k} ,\right)$$

By providing subsets or even true subsets of probability estimation parameters, pairs, tuples and/or sets of allowable probability estimation parameters may be provided that are easy to select, e.g. with respect to one or more criteria. For example, according to a certain layer of the neural network a subset may be chosen with low computational effort, e.g. by just comparing a layer ID to an a priori defined list, in order to choose probability estimation parameters providing an improved decoding efficiency. In addition, such a selection of a subset may be performed according to a certain type of quantization. By providing subsets, advantageous probability estimation parameters may be provided, without a large allocation effort. Instead of checking a plurality of conditions, for example one condition for each probability estimation parameter, one check may be performed, e.g. the beforementioned comparison of a layer ID, or of a context model of a bin of a neural network parameters, to a predefined list or criterion, and choosing based thereon a whole set of probability estimation parameters or probability estimation parameter values. Also, by providing a base set, a signaling effort is reduced, since it may, for example, be sufficient to signal a base set index, rather than an actual parameter value.

According to embodiments of the invention the decoder is configured to choose one or more probability estimation parameters from different sets of useable parameter values or of useable tuples of parameter values in dependence on a quantization mode or wherein the decoder is configured to use different mapping rules, e.g. different mapping tables, mapping an encoded value representing one or more probability estimation parameters, e.g. an encoded index value q, onto one or more probability estimation parameters, e.g.

$$s {h}_{i}^{k} ,$$

in dependence on a quantization mode.

Optionally, the decoder may chose the one or more probability estimation parameters from a first set of useable parameter values or of useable tuples of parameter values for the case that a first quantization mode, e.g. uniform quantization URQ, is used, and the decoder may chose the one or more probability estimation parameters from a second set of useable parameter values for the case that a second quantization mode, e.g. dependent quantization DQ, is used.

Optionally, the sets of useable parameters may, for example, define different associations between an index value included in an encoded bitstream and an associated probability estimation parameter or an associated tuple of probability estimation parameter, wherein, for example, a first set of useable parameters defines a mapping of a given index value onto a first tuple of probability estimation parameters and wherein, for example, a second set of useable parameters defines a mapping of the given index value onto a second tuple of probability estimation parameters which is different from the first tuple.

It has been recognized that different quantization modes may cause different stochastic properties (e.g. correlations) of the neural network parameters and therefore an improved probability estimation (and consequently an improved coding efficiency) may be achieved by adapting the choice of probability estimation parameters according to the quantization method.

According to embodiments of the invention, the decoder is configured to selectively choose one or more probability estimation parameters from a first set of useable parameter values or from a first set of useable tuples of parameter values in case that a uniform quantization, e.g. a uniform reconstruction quantization (URQ), or a time-invariant quantization, of the one or more probability estimation parameters is used, and the decoder is configured to selectively choose one or more probability estimation parameters from a second set of useable parameter values or from a second set of useable tuples of parameter values in case that a variable quantization, e.g. a trellis-coded quantization (TCQ) or a dependent quantization (DQ), of the one or more probability estimation parameters is used, wherein, for example, the variable quantization, like a DQ, may use more context models than the uniform quantization, such that there may be less bins to be decoded per context model in the case of variable quantization.

Alternatively, the decoder is configured to use a first mapping rule, e.g. a first mapping table, mapping an encoded value representing one or more probability estimation parameters, e.g. an encoded index value q, onto one or more probability estimation parameters, e.g. shᵢ^{k}, in case that a uniform quantization, e.g. a uniform reconstruction quantization (URQ) or a time-invariant quantization, of the one or more probability estimation parameters is used.

In addition, the decoder may be configured to use a second mapping rule, e.g. a second mapping table, mapping an encoded value representing one or more probability estimation parameters, e.g. an encoded index value q, onto one or more probability estimation parameters in case that a variable quantization, e.g. a trellis-coded quantization (TCQ) or a dependent quantization (DQ), of the one or more probability estimation parameters is used. Optionally, the variable quantization, like a DQ, may use more context models than the uniform quantization, such that there may be less bins to be decoded per context model in the case of variable quantization.

Furthermore, the first set of useable parameter values is different from the second set of useable parameter values, and the first set of useable tuples of parameter values is different from the second set of useable tuples of parameter values and/or the second mapping rule is different from the first mapping rule.

Consequently, a concept according to the invention may be applied to any form of quantization and is not limited to a certain type of quantization. Moreover, according to characteristics of the neural network parameters, the type of quantization and the used set and/or mapping of probability estimation parameters may be adapted. Therefore, coding efficiency may be improved, in addition to providing a high amount of flexibility.

According to further embodiments of the invention, on average, useable parameter values of the second set of useable parameter values, or for example of the second mapping rule, allow for a faster adaptation of a probability estimate, e.g. to a change of bin value frequencies, than useable parameter values of the first set of useable parameter values, or for example of the first mapping rule. Alternatively, on average, useable tuples of parameter values of the second set of useable tuples of parameter values, or for example of the second mapping rule, allow for a faster adaptation of a probability estimate, e.g. to a change of bin value frequencies, than useable tuples of parameter values of the first set of useable tuples of parameter values, or for example of the first mapping rule.

This embodiment is based on the finding that such a concept results in an improved coding efficiency.

According to further embodiments of the invention, the second set of useable parameter values, or for example the second mapping rule, comprises a useable parameter value which allows for a faster adaptation of a probability estimate, e.g. to a change of bin value frequencies, than useable parameter values, or for example even than all useable parameter values, of the first set of useable parameter values, or for example of the first mapping rule. Alternatively, the second set of useable tuples of parameter values comprises a useable tuple of parameter values which allows for a faster adaptation of a probability estimate, e.g. to a change of bin value frequencies, than useable tuples, or for example even than all useable tuples, of parameter values of the first set of useable tuples of parameter values.

This embodiment is based on the finding that such a concept results in an improved coding efficiency.

According to further embodiments of the invention, the decoder is configured to choose one or more probability estimation parameters from different sets of useable, e.g. allowable, parameter values or of useable, e.g. allowable tuples of parameter values in dependence on a number of parameters of a layer of the neural network, or in dependence on a number of neural network parameters to be decoded using the chosen one or more probability estimation parameters, or in dependence on a number of elements of a layer parameter, e.g. a number of entries of matrix W, or a number of elements of (transposed) vector b, etc..

Alternatively, the decoder is configured to use different mapping rules, e.g. different mapping tables, mapping an encoded value representing one or more probability estimation parameters, e.g. an encoded index value q, onto one or more probability estimation parameters, e.g.

$$s {h}_{i}^{k} ,$$

in dependence on a number of parameters of a layer of the neural network, or in dependence on a number of neural network parameters to be decoded using the chosen one or more probability estimation parameters, or in dependence on a number of elements of a layer parameter, e.g. a number of entries of matrix W, or a number of elements of (transposed) vector b, etc..

It has been found that for the evaluation of the probability of a bit having a certain value, using a context model, an adaptation parameter of the probability estimator may be chosen depending on the number of neural network parameters to be decoded. For example, the higher the number of bins already decoded, the better a stochastic estimation of a probability of such a bin may be determinable. Consequently, the coding efficiency may be improved.

According to further embodiments of the invention, the decoder is configured to selectively choose one or more probability estimation parameters from a first set of useable parameter values or from a first set of useable tuples of parameter values if the number of parameters of a layer of the neural network is below a threshold value, e.g. X=1000, or if the number of neural network parameters to be decoded using the chosen one or more probability estimation parameters is below a threshold value, or if the number of elements of the layer parameter, e.g. a number of entries of matrix W, or a number of elements of (transposed) vector b, etc., is below a threshold value.

In addition, the decoder is configured to selectively choose one or more probability estimation parameters from a second set of useable parameter values or from a second set of useable tuples of parameter values if the number of parameters of a layer of the neural network is above the threshold value, e.g. X=1000, or if the number of neural network parameters to be decoded using the chosen one or more probability estimation parameters is above the threshold value, or if the number of elements of the layer parameter, e.g. a number of entries of matrix W, or a number of elements of (transposed) vector b, etc., is above the threshold value.

Alternatively, the decoder is configured to selectively use a first mapping rule, e.g. a first mapping table, mapping an encoded value representing one or more probability estimation parameters, e.g. an encoded index value q, onto one or more probability estimation parameters, e.g. shᵢ^{k}, if the number of parameters of a layer of the neural network is below a threshold value, e.g. X=1000, or if the number of neural network parameters to be decoded using the chosen one or more probability estimation parameters is below a threshold value, or if the number of elements of the layer parameter, e.g. a number of entries of matrix W or a number of elements of (transposed) vector b, etc., is below a threshold value.

Furthermore, the decoder is configured to selectively use a second mapping rule, e.g. a second mapping table, mapping an encoded value representing one or more probability estimation parameters, e.g. an encoded index value q, onto one or more probability estimation parameters, e.g. shᵢ^{k}, if the number of parameters of a layer of the neural network is above the threshold value, e.g. X=1000, or if the number of neural network parameters to be decoded using the chosen one or more probability estimation parameters is above the threshold value, or if the number of elements of the layer parameter, e.g. a number of entries of matrix W or a number of elements of (transposed) vector b etc., is above the threshold value.

Moreover, the second set of useable parameter values comprises more useable parameter values than the first set of useable parameter values, and the second set of useable tuples of parameter values comprises more useable tuples than the first set of useable tuples of parameter values, and/or the second mapping rule is different from the first mapping rule.

It has been found that a choice of probability estimation parameters according to a certain threshold may provide a computationally inexpensive possibility to adapt the probability estimation parameters. As explained before, statistic adaptation, e.g. of context models, may be performed, for example better, if a large number of parameters is decoded, and therefore probability estimation parameters may be adjusted according to such a number. Also, a signaling overhead (e.g. a number of bits used for an encoding of an index of a probability estimation parameter or of a set of probability estimation parameters) may be reduced, since the signaling is limited to probability estimation parameters (or sets of probability estimation parameters) which are well suited for the currently considered neural network.

According to further embodiments of the invention, the decoder is configured to selectively choose the one or more probability estimation parameters from an increased choice if a number of neural network parameters to be decoded using the chosen one or more probability estimation parameters is larger than or equal to a threshold value, e.g. X=1000.

It has been found that with an increased number of neural network parameters to be decoded, more degrees of freedom concerning the stochastic characteristics of the neural network parameters, for example their correlation, may be present. Therefore, with an increased number of neural network parameters, an increased amount of probability estimation parameters or probability estimation parameters values may be considered in order to improve coding efficiency. Consequently, for small neural networks, a signaling overhead is reduced.

According to further embodiments of the invention, the decoder is configured evaluate a signaling, which may, for example, be included in the encoded bit stream, for example, in the form of a dedicate flag, from which set of useable parameter values, for example small set or large set, e.g. out of a plurality of sets of useable parameter values, which may be different and possibly overlapping subsets of a base set, or from which set of useable tuples of parameter values, for example small set or large set, e.g. out of a plurality of sets of useable tuples of parameter values, which may be different and possibly overlapping subsets of a base set, the one or more probability estimation parameters are elected, e.g. using one or more flags which are decoded, e.g. using a flag “useSecondSubset”.

Alternatively, the decoder is configured evaluate a signaling, which may, for example, be included in the encoded bit stream, for example, in the form of a dedicate flag, indication which mapping rule out of a plurality of mapping rules, e.g. mapping tables, should be used to map an encoded value representing one or more probability estimation parameters, e.g. an encoded index value q, onto one or more probability estimation parameters, e.g. shᵢ^{k}.

With an information about a corresponding set or set of tuples of probability estimation parameters, choice of probability estimation parameters may be performed with low computational costs. In addition, by transmitting such a signaling, an error probability of using different probability estimation parameters in the decoder than in the encoder, may be reduced. Analogously a beneficial mapping rule, e.g. the mapping rule used in the encoder used to encode the encoded bitstream, may be communicated via such a signaling.

For example, by providing such a signaling, the coding may be adapted to the characteristics of the neural network. For example, a first set of useable tuples of parameter values may be selected for a first type of neural network (e.g. because the first set of useable parameter values better fits the statistics of the first type of neural network), and a second set of useable tuples of parameter values may be selected for a second type of neural network. For example, it may be sufficient to signal the selection of the useable set of parameter values only once for a neural network (or at least more rarely than the actual selection of an individual set of parameter values). Consequently, a coding efficiency may be improved.

According to further embodiments of the invention, the decoder is configured to decode one or more index values, for example generally integer values, e.g. an index q or a plurality of indices, describing a probability estimation parameter value, or describing a plurality of probability estimation parameter values, or describing a tuple of probability estimation parameter values, e.g. an index q.

By using index values, probability estimation parameters may be represented in an easily compressible manner. The probability estimation parameters may be encoded and therefore decoded analogously the neural network parameters, providing an improved encoding/decoding efficiency.

According to further embodiments of the invention, the decoder is configured to decode the one or more index values using one or more context models, which may, for example, determine probabilities of bin values of one or more bins used for decoding the index value.

Pursuing one main idea of the invention, the sequence of encoding/decoding of neural network parameters may be applied analogously on the probability estimation parameters. Therefore, probability estimation parameters or bins representing probability estimation parameters, or index values representing probability estimation parameters may be associated with a context model. The benefits of context-depended coding, may be exploited twice, with the encoding/decoding of the probability estimation parameters, used to context-dependent encode/decode the neural network parameters.

According to further embodiments of the invention, the decoder is configured to decode a first bin, e.g. a useNotDefault bin, which describes whether a currently considered index value takes a default value, and the decoder is configured to selectively decode one or more additional bins representing the currently considered index value, or a value derived therefrom, e.g. q-1, in a binary representation, if the currently considered index value does not take the default value.

Optionally, the first bin, indicating whether the currently considered index value takes a default value, is decoded using a context, e.g. considering a probability estimate, while the one or more additional bins are decoded with a fixed length of one bit per bin.

Decoding such a first bin may improve coding efficiency, since no further decoding may be used if the neural network parameters is identified, for example in a first bin decoding step, as a default value. Since the first bin may always be present, a e.g. more complex context dependent coding may provide an increased coding efficiency. For additional bins that may not always be present an less complex coding, e.g. with fixed probabilities may be implemented.

According to further embodiments of the invention, the decoder is configured to decode the one or more index values using a unary code decoding, or using a truncated unary code decoding, or using a variable length code decoding, wherein optionally the code lengths are chosen according to probabilities of occurrence of different index values. Usage of a unary code may allow for a prefix-free and a self-synchronizing code. Furthermore, with a variable length code, index values with a high probability of occurrence may have short code lengths, allowing for an improved efficiency, since symbols and time may be saved with short code lengths for indexes that occur often.

According to further embodiments of the invention the decoder is configured to vary a number of bins or a maximum number of bins, e.g. in case of unary code or Huffmann code, used for decoding the one or more probability estimation parameters, e.g. an integer index q designating a selected probability estimation parameter or a selected tuple of probability estimation parameters, in dependence on a quantization mode used for quantizing the one or more probability estimation parameters, e.g. to adapt to a selected set of useable parameter values or to a selected set of useable tuples of parameter values.

Given a certain quantization method, a certain accuracy or precision of the probability estimation parameters may be achievable. Therefore, a coding efficiency may be improved, if the number of bins or a maximum number of bins may be chosen with respect to the quantization or an expected quantization error.

According to further embodiments of the invention, the decoder is configured to vary a number of bins or a maximum number of bins, e.g. in case of unary code or Huffmann code, used for decoding the one or more probability estimation parameters, e.g. an integer index q designating a selected probability estimation parameter or a selected tuple of probability estimation parameters, in dependence on a number of parameters of a layer of the neural network, or in dependence on a number of neural network parameters to be decoded using the one or more probability estimation parameters, or in dependence on a number of elements of a layer parameter, e.g. a number of entries of matrix W, or a number of elements of (transposed) vector b, etc., e.g. to adapt to a selected set of useable parameter values or to a selected set of useable tuples of parameter values.

Coding efficiency may be improved by varying the number of bins used for decoding probability estimation parameters with respect to a number of neural network parameters to be decoded. A good trade-off between accuracy and computational costs and time effort may be implemented. In addition, stochastic characteristics of bins may be determined depending on the number of neural network parameters, for example adapting a context model more accurately with an increased number of neural network parameters being dependent on said context model.

According to further embodiments of the invention the decoder is configured to switch between different sets of usable parameter values associated with the one or more probability estimation parameters, or between different sets of tuples of useable parameter values associated with a plurality of probability estimation parameters, or between different mapping rules for mapping an encoded value representing one or more probability estimation parameters, e.g. an encoded index value q, onto one or more probability estimation parameters, e.g. shᵢ^{k}. Such a switching may, for example, be performed after switching to neural network parameters of another layer that are to be decoded. This flexibility may allow for a more sophisticated adaptation of the decoding for an increased coding efficiency.

According to further embodiments of the invention the decoder is configured to vary a number of bins or a maximum number of bins, e.g. in case of unary code or Huffmann code, used for decoding the one or more probability estimation parameters, e.g. an integer index q, designating a selected probability estimation parameter or a selected tuple of probability estimation parameters in accordance with a switching between different sets of usable parameter values associated with the one or more probability estimation parameters, or between different sets of tuples of useable parameter values associated with a plurality of probability estimation parameters or between different mapping rules.

For a better understanding, aspects of the beforementioned embodiments concerning a bin representation of probability estimation parameters will be explained in the following in the context of embodiments comprising encoding procedures. Therefore, encoding schemes with optional details are disclosed in the following.

An index q ∈ [0, q_{MAX}] to be encoded is, for example, decomposed into a sequence of bins, which are then encoded. Each bin may, for example, be coded using a context model or using a fixed probability.

The encoding procedure may, for example, be according to one of the following schemes:
1.
$$q - 1 \left⌈l o {g}_{2} \left(s e t L e n g t h - 1\right)\right⌉ s e t L e n g t h Α$$
first bin, for example, useNotDefault, denotes if the estimator parameter to be chosen is different from the default parameter (for example, useNotDefault = 1) or not (for example, useNotDefault = 0). If, for example, useNotDefault = 0, the default parameter is chosen and no further bins are encoded.
2.
$$q - 1 \left⌈l o {g}_{2} \left(s e t L e n g t h - 1\right)\right⌉ s e t L e n g t h$$
Whenever, for example, useNotDefault = 1, a series of bins, e.g. additional bins, is encoded, which denote, for example, the index of the chosen parameter minus one (), indexMinusOne. The number of bins encoded for index is, for example, equal to , where , denotes the number of elements of the set.
3.
$$q - 1 \left⌈l o {g}_{2} \left(s e t L e n g t h - 1\right)\right⌉ s e t L e n g t h$$
4. qqqFor the second procedure a unary code is used. A first bin, for example, greaterThan_0 denotes if the index associated with the probability parameter is greater than zero (for example, greaterThan_0 = 1) or not (for example, greaterThan_0 = 0). If, for example, greaterThan_0 = 0 no further bins are encoded. If, for example, greaterThan_0 = 1, another, e.g. additional, bin is encoded (for example, greaterThan_1), which denotes if index is greater than one (for example, greaterThan_1 = 1) or not (for example, greaterThan_1 = 0). If, for example, greaterThan_1 = 0 no further bins are encoded. If, for example, greaterThan_1 = 0, further bins (greaterThan_X) are encoded in the same manner until a flag greaterThan_ is equal to zero.
5. qqq
6. qq_{MAX}(q_{MAX} - 1)qq_{MAX}(q_{MAX} - 1)This procedure applies a truncated unary code, which is, for example, identical to the unary code used in encoding method 2., except for the case where the index to encode is equal to . In this case, for example, after encoding the bin greaterThan_ no further bins are encoded. For example, at the decoder side the value of is inferred to be , if greaterThan_ is equal to one.
7. qq_{MAX}(q_{MAX} - 1) qq_{MAX}(q_{MAX} - 1)
8. This procedure uses a variable length code, where the code lengths are chosen according to the probability of occurrence of a symbol, for example a Huffman code.

It is to be noted, that any of these schemes may be used in any embodiments of the invention. It will be apparent for a person skilled in the art that the schemes for encoding may be applied for decoding and vice versa.

According to further embodiments of the invention the decoder is configured to determine one or more state variables, e.g. sᵢ^{k} or sₖ, and to derive the probability estimate, e.g. pₖ, using the one or more state variables, e.g. using equations (1) and (2) or using equations (3) and (4) or using equations (3) and (5) or using a linear relation between the one or more state variables and the probability estimate, e.g. P(x,i,k).

State variables provide an efficient mean for an evaluation of a probability model, e.g. a context model, describing a stochastic of a neural network parameter or a bin thereof. As explained before, the state variables may also be used for the coding of the probability estimation parameters. The probability estimation parameters may be decoded using a context model, being evaluated using state variables, that may, for example, be updated based on probability estimation parameters already decoded or decoded, e.g. recently. Using Lookup tables, as shown, for example, in eqn. (1) may, in addition, reduce computational costs.

According to further embodiments of the invention the decoder is configured to derive the probability estimate pₖ from two state variables s₁^{k}, s₂^{k} according to

$${s}_{k} = {\sum }_{i = 1}^{N} \left⌊{s}_{i}^{k} ⋅ {d}_{i}^{k}\right⌋$$

and

$${p}_{k} = \text{} \left\{\begin{matrix}L U T 2 {\left[\left⌊{s}_{k} ⋅ {a}_{k}\right⌋\right]}_{,} & i f \left⌊{s}_{k} ⋅ {a}_{k}\right⌋ \geq 0. \\ 1 - L U T 2 {\left[- \left⌊{s}_{k} ⋅ {a}_{k}\right⌋\right]}_{,} & e l s e\end{matrix} ,\right)$$

wherein optionally LUT2 may be as described herein, and wherein, for example, N=2,

$${d}_{1}^{k} = 16 , {d}_{2}^{k} = 1 \text{and} {\text{a}}_{k} = {2}^{- 7} ,$$

, for example, for all k, wherein k is a context model index.

According to embodiments of the invention the decoder is configured to update the state variables s₁^{k}, s₂^{k} according to

$${s}_{i}^{k} = \left\{\begin{matrix}{s}_{i}^{k} + \left⌊A \left⌊z + \left⌊{s}_{i}^{k} ⋅ {m}_{i}^{k}\right⌋\right⌋ ⋅ {n}_{i}^{k}\right⌋ & i f d e c o d e d s y m b o l i s 1. \\ {s}_{i}^{k} - \left⌊A \left⌊z + \left⌊- {s}_{i}^{k} ⋅ {m}_{i}^{k}\right⌋\right⌋ ⋅ {n}_{i}^{k}\right⌋ & i f d e c o d e d s y m b o l i s 0.\end{matrix}\right) ,$$

wherein

$${m}_{i}^{k}$$

and

$${n}_{i}^{k}$$

are weighting factors, and optionally constitute probability estimation parameters, wherein, for example,

$${m}_{1}^{k}$$

may be equal to 2⁻³ and wherein

$${m}_{2}^{k}$$

may be equal to 2⁻⁷. In addition, A is a lookup table, e.g. storing integer values, which may, for example be defined as described herein. Furthermore, z is an offset value, e.g. a predetermined value, which may, for example, be equal to 16. Optionally,

$${s}_{i}^{k}$$

may be initialized, for example, as described herein.

According to further embodiments of the invention the decoder is configured to vary the weighting factors

$${n}_{i}^{k} ,$$

so as to use different probability estimation parameter values, e.g. different values for

$${n}_{i}^{k} ,$$

for a decoding of different neural network parameters and/or to use different probability estimation parameter values for a decoding of bins associated with different context models and/or to use different probability estimation parameter values for a decoding of neural network parameters associated with different layers of the neural network.

According to further embodiments of the invention a relationship between the weighting factors

$${n}_{i}^{k}$$

and adaptation parameters

$$s {h}_{i}^{k}$$

is defined according to

$${n}_{i}^{k} = {2}^{- s {h}_{i}^{k} + 4} .$$

According to further embodiments of the invention the decoder is configured to decode an information describing the adaptation parameters, e.g. an index q describing a tuple of adaptation parameters, wherein optionally a meaning of the decoded index value q may, for example, be defined as provided in the following table 2 or in table 3, or in table 4 or in table 5 or in table 6 or in table 7. These tables are examples for mapping rules or mapping tables.

In an embodiment, e.g. the embodiments as explained above, an estimator applies, for example, a base set of adaptation parameters, which are N -tuple of adaptation parameters

$$s {h}_{i}^{k} .$$

Then a subset of the base set is chosen. One parameter out of the subset may be signaled.

In a particularly advantageous embodiment, the configuration is, for example, equal to the previous advantageous embodiment, but an estimator is used, which is configured such is identical to the estimator used the current draft of MPEG-7 part 17 standard for compression of neural networks for multimedia content description and analysis and the base set contains, for example, the following 28 pairs for

$$\left(s {h}_{1}^{k} , s {h}_{2}^{k}\right) :$$

TABLE 1

Advantageous base set of adaptations parameters

| | | | |
|---|---|---|---|
| 0 | (0,0) | 14 | (2,3) |
| 1 | (0,1) | 15 | (2,4) |
| 2 | (0,2) | 16 | (2,5) |
| 3 | (0,3) | 17 | (2,6) |
| 4 | (0,4) | 18 | (3,3) |
| 5 | (0,5) | 19 | (3,4) |
| 6 | (0,6) | 20 | (3,5) |
| 7 | (1,1) | 21 | (3,6) |
| 8 | (1,2) | 22 | (4,4) |
| 9 | (1,3) | 23 | (4,5) |
| 10 | (1,4) | 24 | (4,6) |
| 11 | (1,5) | 25 | (5,5) |
| 12 | (1,6) | 26 | (5,6) |
| 13 | (2,2) | 27 | (6,6) |

The subset of size 3 is defined and ordered, for example, such that the indexes q according to Table 2 are assigned, for example, in the case all parameters of a layer are quantized with DQ. The parameter with index q = 0 is denoted, for example, as default parameter:

TABLE 2

Advantageous subset of adaptation parameters for set size 3

| q | Adaptation parameter pair |
|---|---|
| 0 | (1,4) |
| 1 | (0,1) |
| 2 | (2,6) |

For example, one parameter out of the subset is signaled, for example, by encoding q according to encoding scheme 1., where, for example, the bin useNotDefault is encoded using a context model and all other bins are encoded with a fixed length of one bit per bin. In general, according to embodiments of the invention, an arbitrary mix of context dependent coding and/or other coding, e.g. variable length or fixed length coding may be applied to any bin of probability estimation parameters and/or neural network parameters.

In another embodiment (example), the configuration is identical to the previous advantageous embodiment, except for the assigned adaptation parameter pairs and the size of the chosen subset (Table 3), which is equal to 5.

TABLE 3

Advantageous subset of adaptation parameters for set size 5

| q | Adaptation parameter pair |
|---|---|
| 0 | (1,4) |
| 1 | (0,0) |
| 2 | (0,6) |
| 3 | (1,1) |
| 4 | (2,6) |

In another embodiment (example), the configuration is identical to the previous advantageous embodiment, except for assigned adaptation parameter pairs (Table 4):

TABLE 4

Second advantageous subset of adaptation parameters for set size 5

| q | Adaptation parameter pair |
|---|---|
| 0 | (1,2) |
| 1 | (0,0) |
| 2 | (0,5) |
| 3 | (2,5) |
| 4 | (3,4) |

In another mbodiment (example), the configuration is identical to the previous advantageous embodiment, except for the assigned adaptation parameter pairs and the size of the chosen subset (Table 5), which is equal to 9.

TABLE 5

Advantageous subset of adaptation parameters for set size 9

| q | Adaptation parameter pair |
|---|---|
| 0 | (1,4) |
| 1 | (0,0) |
| 2 | (0,5) |
| 3 | (1,1) |
| 4 | (1,2) |
| 5 | (2,4) |
| 6 | (2,6) |
| 7 | (3,4) |
| 8 | (3,5) |

In another embodiment (example), the configuration is identical to the previous advantageous embodiment, except for the assigned adaptation parameter pairs (Table 6).

TABLE 6

Second advantageous subset of adaptation parameters for set size 9

| d | Adaptation parameter pair |
|---|---|
| 0 | (1,3) |
| 1 | (0,0) |
| 2 | (0,5) |
| 3 | (1,1) |
| 4 | (1,6) |
| 5 | (2,4) |
| 6 | (2,6) |
| 7 | (3,5) |
| 8 | (4,4) |

In another embodiment (example), the configuration is identical to the previous advantageous embodiment, except for assigned adaptation parameter pairs (Table 7), the size of the chosen subset (5), and the used quantization method, which uses URQ:

TABLE 7

Advantageous subset of adaptation parameters for set size 5 and URQ

| q | Adaptation parameter pair |
|---|---|
| 0 | (1,4) |
| 1 | (0,6) |
| 2 | (1,1) |
| 3 | (2,6) |
| 4 | (3,4) |

In another embodiment (example), an estimator is used, which is configured such that it is identical to the estimator used the current draft of MPEG-7 part 17 standard for compression of neural networks for multimedia content description and analysis and the base set of Table 1 is used. This is denoted as base configuration.

Whenever a layer parameter is quantized with DQ, the subset (of size 9) of parameter pairs in Table 5 may be applied. If a layer parameter is quantized with URQ the subset in Table 8 may be used.

TABLE 8

Advantageous subset of adaptation parameters for set size 9

| q | Adaptation parameter pair |
|---|---|
| 0 | (1,4) |
| 1 | (0,1) |
| 2 | (0,6) |
| 3 | (1,2) |
| 4 | (1,6) |
| 5 | (2,5) |
| 6 | (2,6) |
| 7 | (3,4) |
| 8 | (3,5) |

In another embodiment (example), the base configuration of the previous advantageous embodiment may be applied.

Whenever the number of elements of a layer parameter is below a threshold X, which may for example be set to X = 1000, the subset with size 3 of parameter pairs, for example, in Table 2, denoted as first subset, may be used. Otherwise, if the number of elements of a layer parameter is greater or equal to the threshold X, the subset with size 9, for example, in Table 5, denoted as second subset, may be used.

In another embodiment (example), the configuration is identical to the previous advantageous embodiment, but instead of using a threshold, a flag (for example, useSecondSubset) is encoded, which determines, for example, the subset to be used. For example, if the flag is equal to zero, the first subset may be used. If the flag is equal to one, the second subset may be used.

According to further embodiments of the invention the encoder is configured to choose one or more probability estimation parameters from a base set or from a true subset of the base set.

Optionally, the base set may comprise a plurality of useable parameter values associated with one or more probability estimation parameters, or the base set may comprise a plurality of tuples of useable parameter values associated with a plurality of probability estimation parameters, e.g. a list of useable pairs

$$\left(s {h}_{1}^{k} , s {h}_{2}^{k}\right) .$$

According to further embodiments of the invention the encoder is configured to choose one or more probability estimation parameters from different sets of useable parameter values or of useable tuples of parameter values in dependence on a quantization mode, for example, such that the encoder chooses the one or more probability estimation parameters from a first set of useable parameter values or of useable tuples of parameter values for the case that a first quantization mode, e.g. uniform quantization URQ, is used, and for example such that the encoder chooses the one or more probability estimation parameters from a second set of useable parameter values for the case that a second quantization mode, e.g. dependent quantization DQ, is used.

According to further embodiments of the invention the encoder is configured to selectively choose one or more probability estimation parameters from a first set of useable parameter values or from a first set of useable tuples of parameter values in case that a uniform quantization, e.g. a uniform reconstruction quantization (URQ) or a time-invariant quantization, of the one or more probability estimation parameters is used, and the encoder is configured to selectively choose one or more probability estimation parameters from a second set of useable parameter values or from a second set of useable tuples of parameter values in case that a variable quantization, e.g. a trellis-coded quantization (TCQ) or a dependent quantization (DQ), of the one or more probability estimation parameters is used. Optionally, the variable quantization, like a DQ, may use more context models than the uniform quantization, such that there may be less bins to be encoded per context model in the case of variable quantization.

In addition, the first set of useable parameter values is different from the second set of useable parameter values, and the first set of useable tuples of parameter values is different from the second set of useable tuples of parameter values.

According to further embodiments of the invention on average, useable parameter values of the second set of useable parameter values allow for a faster adaptation of a probability estimate, e.g. to a change of bin value frequencies, than useable parameter values of the first set of useable parameter values. Alternatively, on average, useable tuples of parameter values of the second set of useable tuples of parameter values allow for a faster adaptation of a probability estimate, e.g. to a change of bin value frequencies, than useable tuples of parameter values of the first set of useable tuples of parameter values.

According to further embodiments of the invention the second set of useable parameter values comprises a useable parameter value which allows for a faster adaptation of a probability estimate, e.g. to a change of bin value frequencies, than useable parameter values or for example even than all useable parameter values, of the first set of useable parameter values. Alternatively, the second set of useable tuples of parameter values comprises a useable tuple of parameter values which allows for a faster adaptation of a probability estimate, e.g. to a change of bin value frequencies, than useable tuples, or for example even than all useable tuples, of parameter values of the first set of useable tuples of parameter values.

According to further embodiments of the invention the encoder is configured to choose one or more probability estimation parameters from different sets of useable, e.g. allowable, parameter values or of useable, e.g. allowable, tuples of parameter values in dependence on a number of parameters of a layer of the neural network, or in dependence on a number of neural network parameters to be encoded using the chosen one or more probability estimation parameters, or in dependence on a number of elements of a layer parameter, e.g. a number of entries of matrix W or a number of elements of (transposed) vector b, etc..

According to further examples of the invention the encoder is configured to selectively choose one or more probability estimation parameters from a first set of useable parameter values or from a first set of useable tuples of parameter values if the number of parameters of a layer of the neural network is below a threshold value, e.g. X=1000, or if the number of neural network parameters to be encoded using the chosen one or more probability estimation parameters is below a threshold value, or if the number of elements of the layer parameter, e.g. a number of entries of matrix W or a number of elements of (transposed) vector b, etc., is below a threshold value.

In addition, the encoder is configured to selectively choose one or more probability estimation parameters from a second set of useable parameter values or from a second set of useable tuples of parameter values if the number of parameters of a layer of the neural network is above the threshold value, e.g. X=1000, or if the number of neural network parameters to be encoded using the chosen one or more probability estimation parameters is above the threshold value, or if the number of elements of the layer parameter, e.g. a number of entries of matrix W or a number of elements of (transposed) vector b, etc., is above the threshold value.

Furthermore, the second set of useable parameter values comprises more useable parameter values than the first set of useable parameter values, and wherein the second set of useable tuples of parameter values comprises more useable tuples than the first set of useable tuples of parameter values.

According to further embodiments of the invention the encoder is configured to selectively choose the one or more probability estimation parameters from an increased choice if a number of neural network parameters to be encoded using the chosen one or more probability estimation parameters is larger than or equal to a threshold value, e.g. X=1000.

According to further embodiments of the invention the encoder is configured to signal from which set of useable parameter values, for example small set or large set, e.g. out of a plurality of sets of useable parameter values which may be different and possibly overlapping subsets of a base set, or from which set of useable tuples of parameter values, for example small set or large set, e.g. out of a plurality of sets of useable tuples of parameter values which may be different and possibly overlapping subsets of a base set, the one or more probability estimation parameters are elected, e.g. using one or more flags which are encoded, e.g. using a flag “useSecondSubset”.

According to further embodiments of the invention the encoder is configured to encode one or more index values, for example generally integer values, e.g. an index q, or a plurality of indices, describing a probability estimation parameter value, or describing a plurality of probability estimation parameter values, or describing a tuple of probability estimation parameter values, e.g. an index q.

According to further embodiments of the invention the encoder is configured to encode the one or more index values using one or more context models, which may, for example, determine probabilities of bin values of one or more bins used for encoding the index value.

According to further embodiments of the invention the encoder is configured to encode a currently considered index value using a first bin, which describes that the currently considered index value takes a default value, or for example using the fist bin only, if the currently considered index value takes the default value.

In addition, the encoder is configured to encode the currently considered index value using a first bin, which describes that the currently considered index value does not take the default value, and using one or more additional bins representing the currently considered index value, or a value derived therefrom, e.g. q-1, in a binary representation, if the currently considered index value does not take the default value.

Optionally, the first bin, indicating whether the currently considered index value takes a default value, is encoded using a context, e.g. considering a probability estimate, while the one or more additional bins are encoded with a fixed length of one bit per bin.

According to further embodiments of the invention the encoder is configured to encode the one or more index values using a unary code, or using a truncated unary code, or using a variable length code, wherein optionally the code lengths are chosen according to probabilities of occurrence of different index values.

According to further embodiments of the invention the encoder is configured to vary a number of bins or a maximum number of bins, e.g. in case of unary code or Huffmann code, used for encoding the one or more probability estimation parameters, e.g. an integer index q designating a selected probability estimation parameter or a selected tuple of probability estimation parameters, in dependence on a quantization mode used for quantizing the one or more probability estimation parameters, e.g. to adapt to a selected set of useable parameter values or to a selected set of useable tuples of parameter values.

According to further embodiments of the invention the encoder is configured to vary a number of bins or a maximum number of bins, e.g. in case of unary code or Huffmann code, used for encoding the one or more probability estimation parameters, e.g. an integer index q designating a selected probability estimation parameter or a selected tuple of probability estimation parameters, in dependence on a number of parameters of a layer of the neural network, or in dependence on a number of neural network parameters to be encoded using the one or more probability estimation parameters, or in dependence on a number of elements of a layer parameter, e.g. a number of entries of matrix W, or a number of elements of (transposed) vector b, etc., e.g. to adapt to a selected set of useable parameter values or to a selected set of useable tuples of parameter values.

According to further embodiments of the invention the encoder is configured to switch between different sets of usable parameter values associated with the one or more probability estimation parameters, or between different sets of tuples of useable parameter values associated with a plurality of probability estimation parameters.

According to further embodiments of the invention the encoder is configured to vary a number of bins or a maximum number of bins, e.g. in case of unary code or Huffmann code, used for encoding the one or more probability estimation parameters, e.g. an integer index q, designating a selected probability estimation parameter or a selected tuple of probability estimation parameters in accordance with a switching between different sets of usable parameter values associated with the one or more probability estimation parameters, or between different sets of tuples of useable parameter values associated with a plurality of probability estimation parameters

According to further embodiments of the invention the encoder is configured to determine one or more state variables, e.g. sᵢ^{k} or sₖ, and to derive the probability estimate, e.g. pₖ, using the one or more state variables, e.g. using equations (1) and (2) or using equations (3) and (4) or using equations (3) and (5) or using a linear relation between the one or more state variables and the probability estimate, e.g. P(x,i,k).

According to further embodiments of the invention the encoder is configured to derive the probability estimate pₖ from two state variables s₁^{k}, s₂^{k} according to

$${s}_{k} = {\sum }_{i = 1}^{N} \left⌊{s}_{i}^{k} ⋅ {d}_{i}^{k}\right⌋$$

and

$${p}_{k} = \left\{\begin{matrix}L U T 2 \left[\left⌊{s}_{k} ⋅ {a}_{k}\right⌋\right] , i f \left⌊{s}_{k} ⋅ {a}_{k}\right⌋ \geq 0. \\ 1 - L U T 2 \left[- \left⌊{s}_{k} ⋅ {a}_{k}\right⌋\right] , e l s e\end{matrix}\right)$$

Optionally, LUT2 may be as described herein, and for example, N=2,

$${d}_{1}^{k} = 16 , {d}_{2}^{k} = 1$$

and aₖ = 2⁻⁷, for example, for all k, wherein k is a context model index.

According to further embodiments of the invention the encoder is configured to update the state variables s₁^{k}, s₂^{k} according to

$${s}_{i}^{k} = \left\{\begin{matrix}{s}_{i}^{k} + \left⌊A \left[z + \text{} \left⌊{s}_{i}^{k} ⋅ {m}_{i}^{k}\right⌋\right] ⋅ {n}_{i}^{k}\right⌋ , I f s y m b o l t o b e e n c o d e d i s 1. \\ {s}_{i}^{k} - \left⌊A \left[z + \left⌊- {s}_{i}^{k} ⋅ {m}_{i}^{k}\right⌋\right] ⋅ {n}_{i}^{k}\right⌋ , I f s y m b o l t o b e e n c o d e d i s 0.\end{matrix}\right)$$

wherein

$${m}_{i}^{k}$$

and

$${n}_{i}^{k}$$

are weighting factors, and for example constitute probability estimation parameters, wherein, for example,

$${m}_{1}^{k}$$

may be equal to 2⁻³ and wherein

$${m}_{2}^{k}$$

may be equal to 2⁻⁷.

In addition, A is a lookup table, e.g. storing integer values, which may, for example be defined as described herein and z is an offset value, e.g. a predetermined value, which may, for example, be equal to 16. Optionally,

$${s}_{i}^{k}$$

may be initialized, for example, as described herein.

According to further embodiments of the invention the encoder is configured to vary the weighting factors

$${n}_{i}^{k} ,$$

so as to use different probability estimation parameter values, e.g. different values for

$${n}_{i}^{k} ,$$

for an encoding of different neural network parameters and/or to use different probability estimation parameter values for an encoding of bins associated with different context models and/or to use different probability estimation parameter values for an encoding of neural network parameters associated with different layers of the neural network.

According to further embodiments of the invention a relationship between the weighting factors

$${n}_{i}^{k}$$

and adaptation parameters

$$s {h}_{i}^{k}$$

is defined according to

$${n}_{i}^{k} = {2}^{- s {h}_{i}^{k} + 4} .$$

According to further embodiments of the invention the encoder is configured to encode an information describing the adaptation parameters, e.g. an index q describing a tuple of adaptation parameters, wherein for example a meaning of the encoded index value q may, for example, be defined as provided in table 2 or in table 3, or in table 4 or in table 5 or in table 6 or in table 7.

All features explained above, and that will be explained in the following, in the context of a decoder are to be understood as features of an encoder according to embodiments of the invention respectively. Vice versa, features explained in the context of an encoder are to be understood as features of a decoder respectively. It will be apparent for a person skilled in the art, that features of the decoder or a method of decoding according to embodiments may be applicable in an identical or similar fashion for a corresponding encoder and vice versa. In this context a decoder may correspond to an encoder, decoding neural network may correspond to encoding neural network parameters, previously decoded neural network parameters or bins thereof may correspond to previously encoded neural network parameters or bins thereof, decoding of different neural network parameters and decoding of bins associated with different context models may correspond to encoding of different neural network parameters and encoding of bins associated with different context models and decoding of neural network parameters associated with different layers of the neural network may correspond to encoding of neural network parameters associated with different layers of the neural network. However, these are just examples of correspondences, for a person skilled in the art it will be apparent, that features and advantages of a decoder according to embodiments of the invention may be interchangeable with features and advantages of an encoder according to embodiments of the invention. The same applies to the explanations regarding methods for encoding/decoding and the Figures in the detailed description of the embodiments.

According to further embodiments of the invention the encoded representation comprises separate encoded representations of separate probability estimation parameters associated with different neural network parameters and/or of separate probability estimation parameters associated with different context models and/or of separate probability estimation parameters associated with different layers of the neural network.

With the separate encoded representations an adaptive choice of the probability estimation parameters may be performed, in order to improve the decoding efficiency.

According to further embodiments of the invention the encoded representation comprises a flag indication which mapping rule out of a plurality of mapping rules is to be used for mapping an encoded value representing one or more probability estimation parameters, e.g. an encoded index value q, onto one or more probability estimation parameters, e.g. shᵢ^{k}.

### BRIEF DESCRIPTION OF THE DRAWINGS

The drawings are not necessarily to scale, emphasis instead generally being placed upon illustrating the principles of the invention. In the following description, various embodiments of the invention are described with reference to the following drawings, in which:

FIG. 1 shows an example for a graph representation of a feed forward neural network;

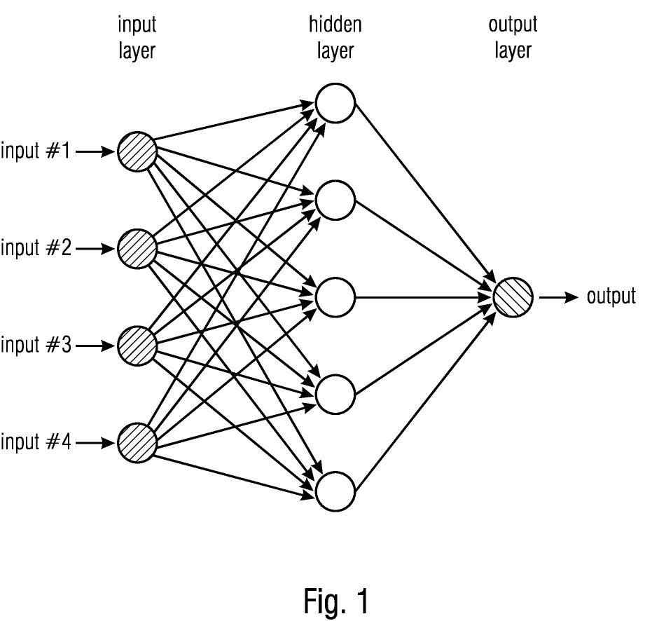

FIG. 2 shows a block schematic diagram of a decoder according to embodiments of the invention;

FIG. 3 shows a schematic representation of an example of a selection of probability estimation parameters according to embodiments of the invention;

FIG. 4 shows a schematic representation of an example of a decoder selection entity according to embodiments of the invention;

FIG. 5 shows a schematic representation of an example of an encoded bitstream and index values describing a probability estimation parameter values according to embodiments of the invention; and

FIG. 6 shows a schematic block diagram of methods according to embodiments of the invention.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

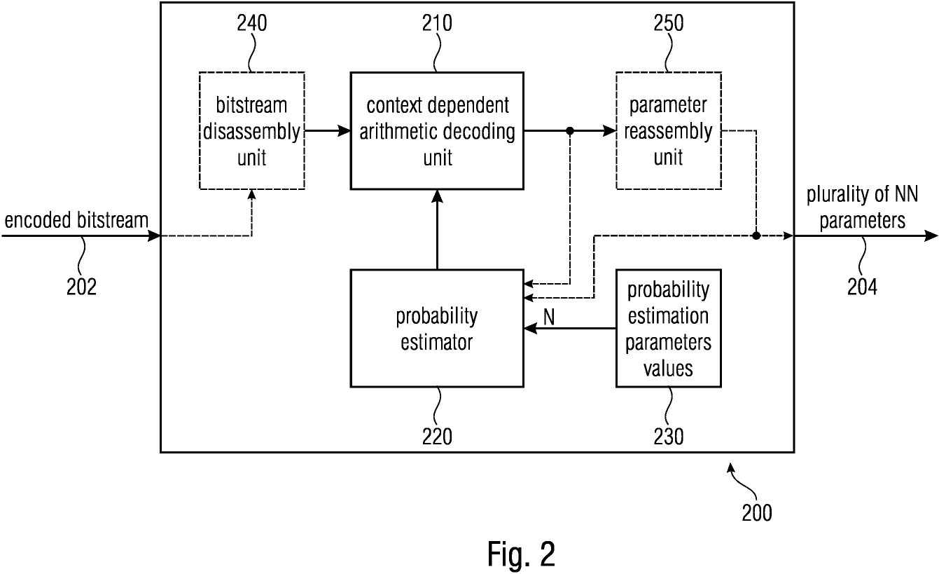

FIG. 2 shows a block schematic diagram of a decoder according to embodiments of the invention. Decoder 200 comprises a context dependent arithmetic decoding unit 210, a probability estimator 220 and probability estimation parameter values 230. Optionally, the decoder 200 comprises a bitstream disassembly unit 240 and a parameter reassembly unit 250. The decoder 200 may be configured to receive an encoded bitstream 202. The encoded bitstream 202 may comprise an information about a plurality of neural network parameters.

The optional bitstream disassembly unit 240 may be configured to convert the encoded bitstream 202 in a processible information for the context dependent arithmetic decoding unit 210. This functionality may be provided by the decoding unit 210, therefore disassembly unit 240 is illustrated only for explanatory purposes. The disassembly unit may be configured to disassemble the encoded bitstream 202 in one part comprising an information about encoded neural network parameters and another part, e.g. flags, indicating a start of the bitstream and/or bits for error correction or other overhead.

The decoding unit 210 may be configured to decode the encoded neural network parameters in order to provide a plurality of, for example decoded, neural network parameters 204. In order to decode the neural network parameters, the decoding unit 210 is configured to receive a probability estimate from the probability estimator 220. The neural network parameters may be encoded in the bitstream 202 as a sequence of bins. One bin or a plurality of bins may represent a neural network parameter. The bins may, for example, be associated with a context, or in other words a probability model. The probability estimate may indicate a probability of a bin to have a certain value, e.g. 1 or 0. The probability estimate may be determined depending on a context of the bin, or in other words its probability model. The probability estimator 220 comprises probability estimation parameters, in order to determine the probability estimate.

The decoder or the context dependent arithmetic decoding unit 210 is configured to use different probability estimation parameters values for a decoding of different neural network parameters. Consequently, stochastic, individual characteristics of neural network parameters may be taken into account by adapting the probability estimation parameters. In addition, or alternatively, the decoder or the context dependent arithmetic decoding unit 210 may be configured to use different probability estimation parameter values for a decoding of bins associated with different context models. Individual bins, or sets of bins may be associated with a context model. The context models may be adapted according to, for example recently, decoded neural network parameters or bins thereof. As a result, for individual bins, or individual context models associated with bins, the parametrization of the probability estimator 220 may be adapted. The optional parameter reassembly unit 250 may be configured to reassemble decoded bins to neural network parameters and/or may be configured to interpret the decoded entities that are provided by the decoding unit 210 in order to provide the plurality of neural network parameters 204. Optionally, the probability estimator 220 may receive feedback information from the output of the decoding unit 210 and/or from the optional parameter reassembly unit 250.

However, decoder 200 may alternatively, or in addition be configured to use different probability estimation parameter values for a decoding of neural network parameters associated with different layers of the neural network. The information of the layer of a certain neural network parameter may be encoded in the bitstream, and may trigger a changing of probability estimation parameters values 230.

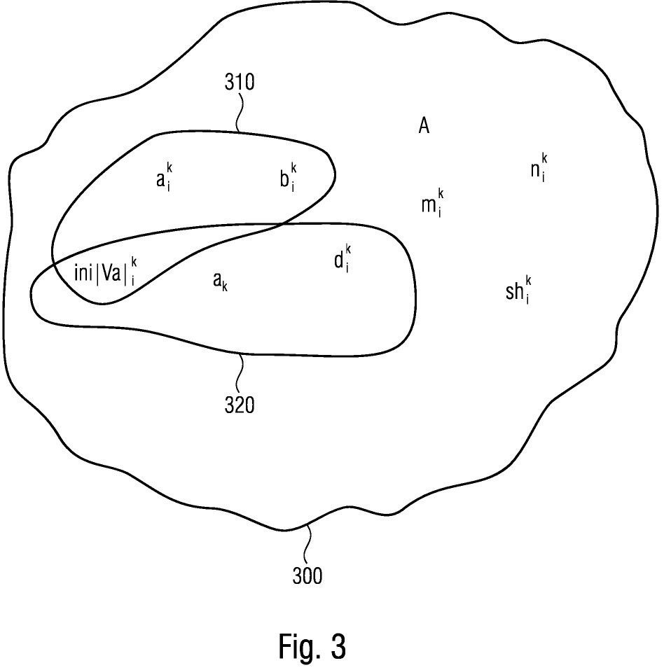

FIG. 3 shows a schematic representation of an example of a selection of probability estimation parameters according to embodiments of the invention. FIG. 3 shows, as an example, probability estimation parameters of approaches 1 - 4 and probability estimation parameters for updating the context model. The decoder may choose one or more probability estimation parameters, e.g. parameters 310 and/or 320 from a base set 300. As shown with parameters 310 and 320 these parameters may be a true subset of the base set 300.

As a result, the decoder may be configured to use not only different probability estimation parameter values but also different probability estimation parameters. The decoder may use any of the approaches 1 to 4, and therefore only need a subset of probability estimation parameters of the base set 300.

In addition, the decoder may not only choose probability estimation parameters but also their values. For example, in a first selection step, the decoder may choose parameters 310. In the next step the decoder may as well choose from different subsets of probability estimation parameter values for these probability estimation parameters. In other words, for each probability estimation parameter, there may be a plurality of sets of admissible probability estimation parameter values and the decoder may choose probability estimation parameters and corresponding values.

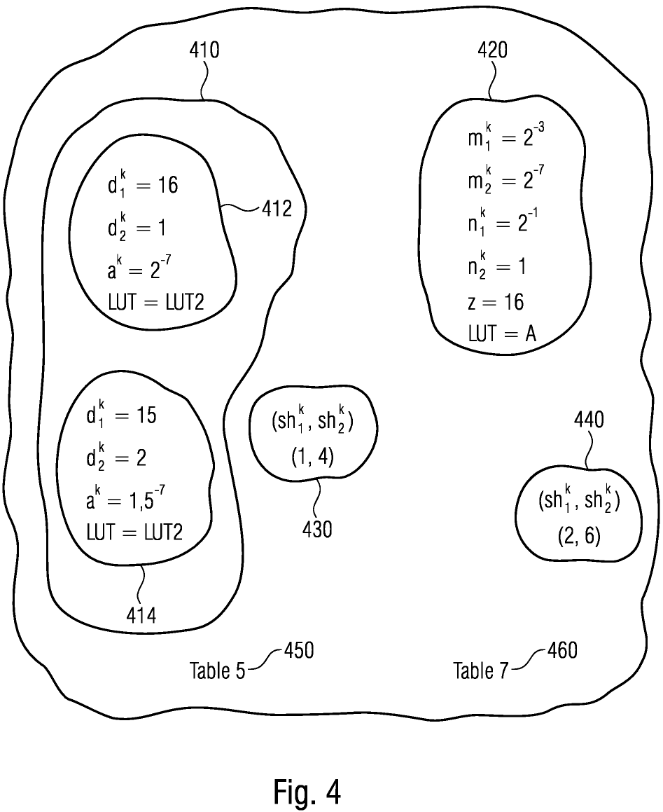

FIG. 4 shows a schematic representation of an example of a decoder selection entity according to embodiments of the invention. The decoder may be configured to choose one or more probability estimation parameters from different sets 410, 420 of usable parameter values, wherein, as an example, set 410 comprises a subset 412 (parameters according to approach 3) and a subset 414. Although the approaches 1 -4 and the update of the state variables have been explained in the context of the encoding and/or decoding of neural network parameters themselves, it is to be noted that similar or equivalent approaches and updates of context models may be performed for the encoding and/or decoding of the probability estimation parameters, hence these parameters are shown here. In addition, or alternatively, the decoder may choose from usable sets of tuples of parameters values 430, 440 and/or from different mapping rules, here shown as an example in the form of the Tables 5, 450, and 7, 460. Choice of probability estimation parameters values, tuples or mappings may be performed based on a quantization mode. It is to be noted, that different sets of usable parameters values may comprise the same probability estimation parameters but with different values. The decoder may choose between the first set 412 and another set 414 comprising, as an example, the values d₁^{k}=15, d₂^{k}= 2, aₖ=1,5⁻⁷ and LUT=LUT2. In other words, an adaption may be performed with regard to the parameters used for encoding/decoding as well as with regard to the respective values of the parameters. However, it is to be noted that according to embodiments only a selection of the values may be performed, e.g. a decoder decision between set 412 and 414, wherein the selection of parameters is not limited to the shown parameters of approach 3.

For example, the decoder may selectively choose one or more probability estimation parameters from a first set 410 of useable parameter values or from a first set of useable tuples 430 of parameter values in case that a uniform quantization of the one or more probability estimation parameters is used. As an example, the decoder may choose between sets 412 and 414 in case of the uniform quantization. On the other hand, the decoder may selectively choose one or more probability estimation parameters from a second set 420 of useable parameter values or from a second set of useable tuples 440 of parameter values in case that a variable quantization of the one or more probability estimation parameters is used. Similarly the decoder may use a first mapping rule 460 mapping an encoded value representing one or more probability estimation parameters onto one or more probability estimation parameters in case that a uniform quantization of the one or more probability estimation parameters is used, and may use a second mapping rule 450, mapping an encoded value representing one or more probability estimation parameters onto one or more probability estimation parameters in case that a variable quantization of the one or more probability estimation parameters is used. First and second sets, tuples and mapping rules may be different from each other.

It is to be noted that the different sets, tuples and mapping rules may comprise different probability estimation parameters, e.g. to perform calculations according to the different approaches 1-4 or may comprise the same probability estimation parameters but with different values. Consequently, the decoder may optionally choose a calculation routine first and then its parametrization, or in other words its values. On the other hand, the decoder may only choose the probability estimation parameters values according to the quantization mode, e.g. choosing between sets 412 and 414 or, for example between tuples 430, 440, describing the same probability estimation parameters but with different values.

As another optional feature, on average, useable parameter values of the second set of useable parameter values or of the second mapping rule may allow for a faster adaptation of a probability estimate, e.g. to a change of bin value frequencies, than useable parameter values of the first set of useable parameter values, or of the first mapping rule. Alternatively, on average, useable tuples of parameter values of the second set of useable tuples of parameter values, or of the second mapping rule, may allow for a faster adaptation of a probability estimate, e.g. to a change of bin value frequencies, than useable tuples of parameter values of the first set of useable tuples of parameter values, or of the first mapping rule.

Optionally, the second set of useable parameter values, or the second mapping rule, may comprise a useable parameter value which allows for a faster adaptation of a probability estimate, e.g. to a change of bin value frequencies, than useable parameter values, or even than all useable parameter values, of the first set of useable parameter values, or of the first mapping rule. Alternatively, the second set of useable tuples of parameter values comprises a useable tuple of parameter values which allows for a faster adaptation of a probability estimate, e.g. to a change of bin value frequencies, than useable tuples, or even than all useable tuples, of parameter values of the first set of useable tuples of parameter values.

Furthermore, sets 410 and 420 may be useable, or for example allowable, parameter values, tuples 430, 440 may be useable, or for example allowable, tuples. Decoder choice of such sets or tuples may be performed based on, or in dependence on a number of parameters of a layer of the neural network or in dependence on a number of neural network parameters to be decoded using the chosen one or more probability estimation parameters, or in dependence on a number of elements of a layer parameter. Analogously, usage of different mapping rules 450 ,460 may be performed by the decoder in dependence on a number of neural network parameters to be decoded using the chosen one or more probability estimation parameters, or in dependence on a number of elements of a layer parameter.

As another optional feature, the decoder may be configured to selectively choose one or more probability estimation parameters from a first set of useable parameter values or from a first set of useable tuples of parameter values if the number of parameters of a layer of the neural network is below a threshold value, e.g. X=1000, or if the number of neural network parameters to be decoded using the chosen one or more probability estimation parameters is below a threshold value, or if the number of elements of the layer parameter is below a threshold value.

Additionally, the decoder may be configured to selectively choose one or more probability estimation parameters from a second set of useable parameter values or from a second set of useable tuples of parameter values if the number of parameters of a layer of the neural network is above the threshold value or if the number of neural network parameters to be decoded using the chosen one or more probability estimation parameters is above the threshold value, or if the number of elements of the layer parameter is above the threshold value.

Alternatively, the decoder is configured to selectively use a first mapping rule mapping an encoded value representing one or more probability estimation parameters onto one or more probability estimation parameters if the number of parameters of a layer of the neural network is below a threshold value or if the number of neural network parameters to be decoded using the chosen one or more probability estimation parameters is below a threshold value, or if the number of elements of the layer parameter is below a threshold value, and the decoder may be configured to selectively use a second mapping rule mapping an encoded value representing one or more probability estimation parameters onto one or more probability estimation parameters if the number of parameters of a layer of the neural network is above the threshold value or if the number of neural network parameters to be decoded using the chosen one or more probability estimation parameters is above the threshold value, or if the number of elements of the layer parameter is above the threshold value;

in this case, the second set of useable parameter values may comprise more useable parameter values than the first set of useable parameter values, and the second set of useable tuples of parameter values may comprise more useable tuples than the first set of useable tuples of parameter values. In addition, or alternatively, the second mapping rule may be different from the first mapping rule.

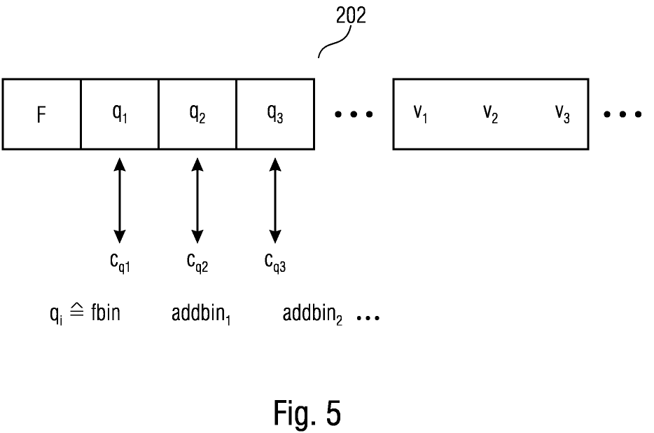

FIG. 5 shows a schematic representation of an example of an encoded bitstream and index values describing probability estimation parameter values according to embodiments of the invention. As an example, the bitstream 202 comprises a signaling in the form of a flag indication F or in other words a flag F. However, the signaling may be transmitted in any suitable way. The decoder may evaluate flag F in order to determine from which set of useable parameter values or from which set of useable tuples of parameter values the one or more probability estimation parameters are elected. Alternatively, the decoder may be configured to evaluate the signaling indication which mapping rule out of a plurality of mapping rules should be used to map an encoded value representing one or more probability estimation parameters onto one or more probability estimation parameters. Hence, the decoder’s choice of sets, tuples and or mappings according to FIG. 4 may be based on the signaling, e.g. in the form of an encoded flag F. Optional bitstream disassembly unit 240, may for example, disassemble bitstream 202 in the flag for indicating the set, tuple and/or mapping to be used for decoding and in an information about the probability estimation parameter values.

As shown in FIG. 5 the bitstream 202 may comprise one or more index values qᵢ, (here as an example shown for i=1, 2 and 3), for example integer values, describing a probability estimation parameter value, or describing a plurality of probability estimation parameter values, or describing a tuple of probability estimation parameter values. In other words, the index values qᵢ may be an encoded representation of one or more probability estimation parameters.

The decoder may be configured to decode the one or more index values qᵢ, for example using the signaling. In addition, the one or more index values qᵢ may be associated with one or more context models c_{qi}. and the decoder may be configured to decode the index values qᵢ using the context models c_{qi}.

The index values may be represented by one or more bins. A first bin, for example as shown fbin, may describe whether a currently considered index value takes a default value. In case the index value takes the default value, the index value may comprise only the one bin, since the index value is already determined by the first bin. Otherwise, the index value may be represented with one or more additional bins, e.g. in the form of bins addbinⱼ, as an example shown with j = 1, 2, 3. The decoder may be configured to decode the first bin and the optional additional bins. Any of these bins may be associated with a context, for example individually. Optionally context c_{qi} of index value qᵢ may be associated with the first bin of the index value and the additional bins may be decoded with a fixed length per bin.

In addition, the bitstream 202 comprises integer multiples rᵢ, as an example shown with i = 1, 2, 3, associated with neural network parameters. Based on the index values qᵢ an adaptation of a context of an arithmetic decoding of encoded neural network parameters, which may be encoded weight parameters of the neural network, represented by integer multiples rᵢ, may be performed.

As another optional feature, the decoder may be configured to decode the one or more index values using a unary code decoding, or using a truncated unary code decoding, or using a variable length code decoding, wherein, for example, the code lengths are chosen according to probabilities of occurrence of different index values. According to embodiments any suitable coding technique may be applied, for example individually for different index values, providing improved flexibility and coding efficiency.

In addition, the decoder may be configured to vary a number of bins or a maximum number of bins used for decoding the one or more probability estimation parameters in dependence on a quantization mode used for quantizing the one or more probability estimation parameters and/or in dependence on a number of parameters of a layer of the neural network, or in dependence on a number of neural network parameters to be decoded using the one or more probability estimation parameters, or in dependence on a number of elements of a layer parameter.

As another optional feature, the decoder may be configured to switch between different sets of usable parameter values associated with the one or more probability estimation parameters, or between different sets of tuples of useable parameter values associated with a plurality of probability estimation parameters, or between different mapping rules for mapping an encoded value representing one or more probability estimation parameters onto one or more probability estimation parameters. The decoder may switch between sets 410 (and/or between sets 412, 414) and 420 and/or between tuples 430, 440 and/or different mappings 450, 460 as shown in FIG. 4.

Furthermore, the beforementioned variation of number of bins or maximum number of bins may be performed by the decoder in accordance with a switching between different sets, tuples and/or mapping rules.

In addition, the decoder may be configured to determine one or more state variables, e.g. sᵢ^{k} or sₖ, and to derive the probability estimate, e.g. pₖ, using the one or more state variables.

Moreover, encoded bitstream 202 may be an encoded representation of weight parameters of a neural network, comprising a plurality of encoded weight parameters of the neural network in the form of the integer multiples rᵢ and an encoded representation of one or more probability estimation parameters, namely the index values qᵢ.

As shown, the encoded representation in the form of the encoded bitstream 202 may comprise separate encoded representations of separate probability estimation parameters, namely index values qᵢ, (here as an example shown for i=1, 2 and 3). These index values qᵢ may be associated with different neural network parameters, e.g. q₁->r₁, q₂->r₂, .... Alternatively or in addition, as shown, separate probability estimation parameters qᵢ may be associated with different context models c_{qi}. As another optional feature, separate probability estimation parameters may be associated with different layers of the neural network.

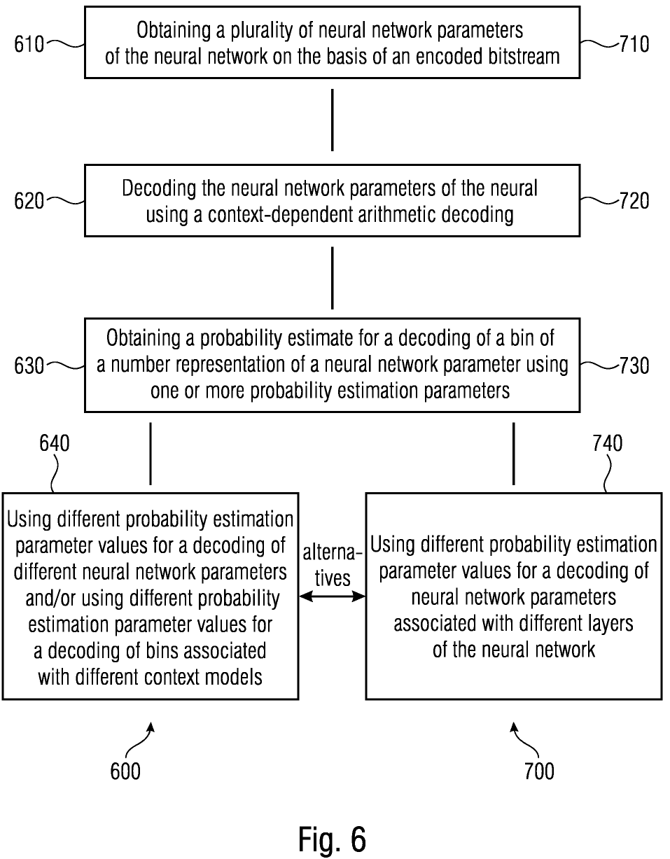

FIG. 6 shows a schematic block diagram of methods according to embodiments of the invention. FIG. 6 shows methods 600, 700 for decoding weight parameters of a neural network. The methods 600 and 700 comprise obtaining 610, 710 a plurality of neural network parameters, e.g., at least one of entries wᵢ of matrix W, b, µ, σ², σ, _{Y},and/or β, of the neural network on the basis of an encoded bitstream, a decoding 620, 720 the neural network parameters of the neural network, e.g., a quantized version thereof, using a context-dependent arithmetic decoding, e.g., using a context-adaptive binary arithmetic decoding (CABAC). Optionally, probabilities of bin values are determined for different contexts, wherein, for example, each bin is associated with a context. Methods 600, 700 further comprise obtaining 630, 730 a probability estimate, e.g. P(t) or pₖ, which may, for example, be associated with a context, for a, optionally arithmetic, decoding of a bin of a number representation of a neural network parameter, e.g. on the basis of one or more previously decoded neural network parameters or bins thereof, using one or more probability estimation parameters, e.g., probability estimator parameters, e.g.

$$N , {a}_{i}^{k} , {b}_{i}^{k} , {a}_{k} , {d}_{i}^{k} , A , {m}_{i}^{k} , {n}_{i}^{k} , s {h}_{i}^{k} , i n i t V a {l}_{i}^{k} .$$

Method 600 comprises in addition using 640 different probability estimation parameter values for a decoding of different neural network parameters and/or using different probability estimation parameter values for a decoding of bins associated with different context models, e.g. cₖ.

On the other hand, method 700 comprises in addition using 740 different probability estimation parameter values for a decoding of neural network parameters associated with different layers of the neural network.

### Further Embodiments and Aspects

In the following further embodiments comprising aspects and features that may be incorporated in any of the preceding embodiments are disclosed.

### Efficient Representation of Parameters (Examples, Details are Optional)

The parameters W, b, µ, σ², γ, and β shall collectively be denoted parameters of a layer or layer parameters. They usually need to be signaled in a bitstream (e.g. in an encoded video representation, for example, if the neural network is used in a video decoder). For example, they could be represented as 32 bit floating point numbers or they could, for example, be quantized to an integer representation, also denoted as quantization indices. Note that ∈ is usually not signaled in the bitstream.

For example, a particularly efficient approach for encoding such parameters employs a uniform reconstruction quantizer (URQ) where, for example, each value is represented as integer multiple of a so-called quantization step size value. The corresponding floating point number can, for example, be reconstructed by multiplying the integer with the quantization step size, which is usually (but not necessarily) a single floating point number. However, for example, efficient implementations for neural network inference (that is, calculating the output of the neural network for an input) employ integer operations whenever possible. Therefore, it may be undesirable to use parameters to be reconstructed to a floating point representation.

In another efficient approach for encoding the parameters, a set of quantizers is applied where each value is, for example, represented as integer multiple of a quantization step size value. Usually, for example, each quantizer in the set employs a disjoint set of integer multiples of the quantization step size parameter as applicable reconstruction values, but two or more quantizers may share one or more reconstruction values. The applied quantizer depends, for example, on the values of previous quantization indices in coding order. The corresponding floating point number can, for example, be reconstructed by multiplying the integer with the quantization step size, which is usually, for example, a floating point number which depends on the chosen quantizer.

An example for such a quantizer design is trellis coded quantization (TCQ), also denoted as dependent quantization (DQ).

In an embodiment a set of two quantizers is used. The first quantizer employs, for example, all even multiples of the quantization step size including zero, and the second quantizer employs all the even multiples of the quantization step size including zero.

### Entropy Coding and Probability Estimation (Examples, Details are Optional)

The quantization indices that are output, for example, by the quantization method are then entropy coded using a suitable entropy coding method.

A particularly suitable entropy coding method for encoding such quantization indices is Context-based Adaptive Binary Arithmetic Coding, also denoted as CABAC. For this, each quantization index is, for example, decomposed into a sequence of binary decisions, so-called bins.

Usually, for example, each bin is associated with a probability model, also denoted as context model, which models the statistics of the associated bins, for example, using a probability estimation method.

A probability estimator is an apparatus, that models the probability P(t) for a bin being equal to x, where x ∈ {0,1} , for example, based on already coded bins associated with the probability estimator.

For example, probability estimators have several parameters, denoted as probability estimator parameters or estimator parameters (or also as probability estimation parameters), that affect the probability estimates, e.g. the adaptation rate. Usually, those estimator parameters are, for example, chosen globally, depending on the application scenario, e.g. encoding of neural network parameters. Thus, for example, in neural network encoding, each neural network parameter applies the same set of estimator parameters.

But, it has been found that the compression efficiency can be improved by selecting optimized estimator parameters for a current neural network parameter. So, according to an aspect, the basic idea is to select suitable estimator parameters out of a set of parameters, which are then signaled to the decoder.

### Typical Estimator Design (Example, Details are Optional)

First, a typical estimator design, that is applied in neural network compression, is described.

For example, for each context model cₖ, one or more state variables

$${s}_{i}^{k} , … , {s}_{N}^{k}$$

are maintained with N ≥ 1. Each state variable

$${s}_{i}^{k}$$

is implemented, for example, as signed integer value and represents, for example, a probability value

$$P \left({s}_{i}^{k} , i , k\right) = {p}_{i}^{k} .$$

The probability estimate pₖ of a context model cₖ shall be defined, for example, as weighted sum of the probability values

$${p}_{i}^{k}$$

of all state variables of the context model.

State variables shall advantageously but not necessarily have the following properties:
1.
$$\text{If} {s}_{i}^{k} = 0 ,$$
then
$${p}_{i}^{k} = 0.5.$$
2. Larger values for
$${s}_{i}^{k}$$
correspond to larger
$${p}_{i}^{k} .$$
3.
$$P \left(- {s}_{i}^{k} , i , k\right) = 1 - P \left({s}_{i}^{k} , i , k\right) .$$

Consequently, negative state variables may, for example, correspond to

$${p}_{i}^{k} < 0.5.$$

In general, it is possible to specify different functions P(·) for each state variable of each context model.

### Exemplary Configuration for Associating State Variables with Probability Values (Example, Details are Optional)

There exist many useful ways of associating state variables with probability values, i.e., of implementing P(·). For example, a state representation that is used in neural network compression can be achieved with the following equation:

$$p \left(x , i , k\right) = \left\{\begin{matrix}0.5 ⋅ {α}^{\left⌊x ⋅ {β}_{i}^{k}\right⌋} , i f x \geq 0 , \\ 1 - 0.5 ⋅ {α}^{\left⌊- x ⋅ {β}_{i}^{k}\right⌋} , e l s e .\end{matrix}\right)$$

$${β}_{i}^{k}$$

is a weighting factor. α is a parameter with 0 < α < 1.

To achieve, for example, a configuration comparable to the one used in the current draft of MPEG-7 part 17 standard for compression of neural networks for multimedia content description and analysis, which uses two states

$$\left(N = 2 , {s}_{1}^{k} , {s}_{2}^{k}\right) ,$$

set α ≈0.99894079 and

$${β}_{1}^{k} = 16$$

and

$${β}_{2}^{k} = 1$$

for all k.

This exemplary configuration shall give some insight about how state variables could be defined. In general, it is not necessary to define P(·) because it is not directly used, as will be seen in the following. Instead, it often results from the actual implementation of the individual parts.

### Initialization of State Variables (Example, Details are Optional)

Before encoding or decoding the first symbol with a context model, all state variables are optionally initialized with sane values, denoted as

$$i n i t V a {l}_{i}^{k} ,$$

that may, for example, be optimized to the compression application.

### Derivation of a Probability Estimate From State Variables (Examples, Details are Optional)

For encoding or decoding of a symbol, a probability estimate is derived from the state variables of a context model. Three alternative approaches are presented in the following as examples. Approach 1 yields more accurate results than approach 2 and approach 3, but also has a higher computational complexity.

### Approach 1 Example

This approach consists of two steps. Firstly, each state variable

$${s}_{i}^{k}$$

of a context model is converted into a probability value

$${p}_{i}^{k} .$$

Secondly, the probability estimate pₖ is derived as weighted sum of the probability values

$${p}_{i}^{k} .$$

### Step 1:

A lookup table LUT1 is employed for converting a state variable

$${s}_{i}^{k}$$

into the corresponding probability value

$${p}_{i}^{k} ,$$

for example according to Eq. (1).

$${p}_{i}^{k} = \left\{\begin{matrix}L U T 1 \left[\left⌊{s}_{i}^{k} ⋅ {a}_{i}^{k}\right⌋\right] , \\ 1 - L U T 1 \left[\left⌊- {s}_{i}^{k} ⋅ {a}_{i}^{k}\right⌋\right] ,\end{matrix} \begin{matrix}i f {s}_{i}^{k} \geq 0. \\ e l s e .\end{matrix}\right)$$

LUT1 is a lookup table containing probability values.

$${a}_{i}^{k}$$

is a weighting factor that adapts

$${s}_{i}^{k}$$

to the size of LUT1.

### Step 2:

The probability estimate pₖ is derived from the probability values

$${p}_{i}^{k} ,$$

for example according to:

$${p}_{k} = {\sum }_{i = 1}^{N} {p}_{i}^{k} ⋅ {b}_{i}^{k}$$

$${b}_{i}^{k}$$

is a weighting factor that controls the influence of the individual state variables.

### Approach 2 Example

An alternative approach for deriving the probability estimate from the state variables is presented in the following. It yields less accurate results and has a lower computational complexity. Firstly, a weighted sum sₖ of the state variables is derived, for example, according to:

$${s}_{k} = {\sum }_{i = 1}^{N} \left⌊{s}_{i}^{k} ⋅ {d}_{i}^{k}\right⌋$$

$${d}_{i}^{k}$$

is a weighting factor that controls the influence of each state variable.

Secondly, the probability estimate pₖ is derived from the weighted sum of state variables sₖ, for example according to:

$${p}_{k} = \left\{\begin{matrix}L U T 2 \left[\left⌊{s}_{k} ⋅ {a}_{k}\right⌋\right] , \\ 1 - L U T 2 \left[\left⌊- {s}_{k} ⋅ {a}_{k}\right⌋\right] ,\end{matrix} \begin{matrix}i f {s}_{k} \geq 0. \\ e l s e .\end{matrix}\right)$$

LUT2 is a lookup table containing probability estimates. aₖ is a weighting factor that adapts sₖ to the size of LUT2.

### Approach 3 Example

A further alternative approach for deriving the probability estimate from the state variables is presented in the following. Firstly, the weighted sum sₖ of the state variables is derived, for example, as in approach 2. Secondly, the probability estimate pₖ is derived from the weighted sum of state variables sₖ, for example according to:

$${p}_{k} = \left\{\begin{matrix}L U T 2 \left[\left⌊{s}_{k} ⋅ {a}_{k}\right⌋\right] , \\ 1 - L U T 2 \left[- \left⌊{s}_{k} ⋅ {a}_{k}\right⌋\right] ,\end{matrix} \begin{matrix}i f \left⌊{s}_{k} ⋅ {a}_{k}\right⌋ \geq 0. \\ e l s e\end{matrix}\right)$$

LUT2 is a lookup table containing probability estimates.

### Approach 4 Example

A further approach uses a linear relation between the state values and the probability P(x, i, k). The derivation of the probability estimate is, for example, using the approach of equation (2). An example of approach 4 is the probability estimation scheme used in the current draft of Versatile Video Coding (VVC).

To achieve, for example, a configuration used in the current draft of MPEG-7 part 17 standard for compression of neural networks for multimedia content description and analysis, the method of approach 3 is used, for example, with

$${d}_{1}^{k} = 16 , {d}_{2}^{k} = 1$$

and aₖ = 2⁻⁷ for all k. The look-up table containing the probability estimates is, for example,:

$$\begin{matrix}L U T 2 = \\ \left\{\begin{matrix}0.5000 , 0.4087 , 0.3568 , 0.3116 , 0.2721 , 0.2375 , 0.2074 , 0.1811 , \\ 0.1581 , 0.1381 , 0.1206 , 0.1053 , 0.0919 , 0.0803 , 0.0701 , 0.0612 , \\ 0.0534 , 0.0466 , 0.0407 , 0.0356 , 0.0310 , 0.0271 , 0.0237 , 0.0207 , \\ 0.0180 , 0.0158 , 0.0138 , 0.0120 , 0.0105 , 0.0092 , 0.0080 , 0.0070\end{matrix}\right\}\end{matrix}$$

### Update of State Variables (Examples, Details are Optional)

After the encoding or decoding of a symbol, one or more state variables of a context model may be updated in order to track the statistical behaviour of the symbol sequence.

The update is, for example, carried out as follows:

$$\begin{matrix}{s}_{i}^{k} = \\ \left\{\begin{matrix}{s}_{i}^{k} + \left⌊A \left[z + \left⌊{s}_{i}^{k} ⋅ {m}_{i}^{k}\right⌋\right] ⋅ {n}_{i}^{k}\right⌋ , & I f s y m b o l t o b e e n c o d e d i s 1. \\ {s}_{i}^{k} + \left⌊A \left[z + \left⌊- {s}_{i}^{k} ⋅ {m}_{i}^{k}\right⌋\right] ⋅ {n}_{i}^{k}\right⌋ , & I f s y m b o l t o b e e n c o d e d i s 0.\end{matrix}\right)\end{matrix}$$

A is a lookup table storing, for example, integer values.

$${m}_{i}^{k}$$

and

$${n}_{i}^{k}$$

are weighting factors that control, for example, the update ‘agility’. The factors

$${n}_{i}^{k}$$

can be written, for example, according to

$${n}_{i}^{k} = {2}^{- s {h}_{i}^{k} + 4} ,$$

where

$$s {h}_{i}^{k}$$

also denoted as adaptation parameter. z is an offset that ensures, for example, that look table A is accessed only with nonnegative values.

The values in lookup table A can, for example, be chosen so that

$${s}_{i}^{k}$$

stays in a particular given interval.

Usually, the values of look-up A approximate, for example, an update function. Alternatively, it is, for example, also possible to simply use the related update function for the state updates.

For example, the estimation method of VVC, following approach 4, applies update functions for the state update and uses bit shifts, which, for example, determine the ‘agility’ of the update. This corresponds, for example, to the adaptation parameters described above. The invention (see below) can be applied to those in the same manner.

To achieve, for example, a configuration used in the current draft of MPEG-7 part 17 standard for compression of neural networks for multimedia content description and analysis, the parameters are chosen, for example, such that

$${m}_{1}^{k} = {2}^{- 3} , {m}_{2}^{k} = {2}^{- 7}$$

and

$${n}_{1}^{k} = {2}^{- 1} , {n}_{2}^{k} = 1 ,$$

for all k, and z = 16. The look-up table A is, for example: A = {157, 143, 129, 115, 101, 87, 73, 59, 45, 35, 29, 23, 17, 13, 9, 5, 4, 4, 4, 4, 4, 4, 4, 4, 4, 4, 4, 4, 4, 4, 4, 0 }.

Before encoding a symbol,

$${s}_{1}^{k}$$

shall, for example, be initialized with a value from the interval [-127,127] and

$${s}_{2}^{k}$$

shall be initialized, for example, with a value from the interval [-2047, 2047].

Consequently,

$${s}_{1}^{k}$$

can, for example, be implemented with an 8 bit signed integer value and

$${s}_{2}^{k}$$

can, for example, be implemented with a 12 bit signed integer.

### Aspect of the Invention (Details are Optional)

In the following the parameters, i.e.

$$N , {a}_{i}^{k} , {b}_{i}^{k} , {a}_{k} , {d}_{i}^{k} , A , {m}_{i}^{k} , {n}_{i}^{k} , s {h}_{i}^{k} , i n i t V a {l}_{i}^{k}$$

and any other parameter related to the probability estimator (context model) shall be collectively denoted as probability estimator parameters or estimator parameters (or probability estimation parameters).

Usually, for example, for each estimator parameter one fixed instance out of a base set of probability estimator parameters is chosen for the entire network. The values of the base set may also be N-tuples of estimator parameters, according to the number of applied states N. According to an aspect of the invention, the probability estimation, and thus the compression efficiency, can, for example, be improved, if the parameters are chosen individually for each parameter or a subset of parameters of a layer (i.e. W, b, µ, σ², y, and β) and/or context model cₖ.

The estimator parameter to be used is, for example, determined among the parameters of a set of parameters, which can, for example, be the base set or any subset of the base set. Each parameter of the set may, for example, be associated with an integer index q. For example, one parameter of the set may be denoted as default parameter. Usually the default parameter is, for example, associated with an integer index equal to zero. The index associated with the chosen estimator parameter is then, for example, signaled to the decoder.

### Encoding Schemes (Examples, Details are Optional)

The index q ∈ [0, q_{MAX}] to be encoded is, for example, decomposed into a sequence of bins, which are then encoded. Each bin may, for example, be coded using a context model or using a fixed probability.

The encoding procedure may, for example, be according to one of the following schemes:
1. A first bin, for example, useNotDefault, denotes if the estimator parameter to be chosen is different from the default parameter (for example, useNotDefault = 1) or not (for example, useNotDefault = 0). If, for example, useNotDefault = 0, the default parameter is chosen and no further bins are encoded. Whenever, for example, useNotDefault = 1, a series of bins is encoded, which denote, for example, the index of the chosen parameter minus one (q - 1), indexMinusOne. The number of bins encoded for index is, for example, equal to [log₂(setLength - 1)], where setLength, denotes the number of elements of the set.
2. For the second procedure an unary code is used. A first bin, for example, greaterThan_0 denotes if the index q associated with the probability parameter is greater than zero (for example, greaterThan_0 = 1) or not (for example, greaterThan_0 = 0). If, for example, greaterThan_0 = 0 no further bins are encoded. If, for example, greaterThan_0 = 1, another bin is encoded (for example, greaterThan_1), which denotes if index q is greater than one (for example, greaterThan_1 = 1) or not (for example, greaterThan_1 = 0). If, for example, greaterThan_1 = 0 no further bins are encoded. If, for example, greaterThan_1 = 0, further bins (greaterThan_X) are encoded in the same manner until a flag greaterThan_q is equal to zero.
3. This procedure applies a truncated unary code, which is, for example, identical to the unary code used in encoding method 2. , except for the case where the index to encode q is equal to q_{MAX}. In this case, for example, after encoding the bin greaterThan_(q_{MAX} - 1) no further bins are encoded. For example, at the decoder side the value of q is inferred to be q_{MAX,} if greaterThan_(q_{MAX} - 1) is equal to one.
4. This procedure uses a variable length code, where the code lengths are chosen according to the probability of occurrence of a symbol, for example a Huffman code.

### Advantageous Embodiments (Examples, Details are Optional)

In an embodiment an estimator applies, for example, a base set of adaptation parameters, which are N-tuple of adaptation parameters

$$s {h}_{i}^{k} .$$

Then a subset of the base set is chosen. One parameter out of the subset is signaled.

In a particularly advantageous embodiment, the configuration is, for example, equal to the previous advantageous embodiment, but an estimator is used, which is configured such is identical to the estimator used the current draft of MPEG-7 part 17 standard for compression of neural networks for multimedia content description and analysis and the base set contains, for example, the following 28 pairs for

$$\left(s {h}_{i}^{k} , s {h}_{2}^{k}\right) :$$

TABLE 9

Advantageous base set of adaptations parameters

| | | | |
|---|---|---|---|
| 0 | (0,0) | 14 | (2,3) |
| 1 | (0,1) | 15 | (2,4) |
| 2 | (0,2) | 16 | (2,5) |
| 3 | (0,3) | 17 | (2,6) |
| 4 | (0,4) | 18 | (3,3) |
| 5 | (0,5) | 19 | (3,4) |
| 6 | (0,6) | 20 | (3,5) |
| 7 | (1,1) | 21 | (3,6) |
| 8 | (1,2) | 22 | (4,4) |
| 9 | (1,3) | 23 | (4,5) |
| 10 | (1,4) | 24 | (4,6) |
| 11 | (1,5) | 25 | (5,5) |
| 12 | (1,6) | 26 | (5,6) |
| 13 | (2,2) | 27 | (6,6) |

The subset of size 3 is defined and ordered, for example, such that the indexes q according to Table 2 are assigned, for example, in the case all parameters of a layer are quantized with DQ. The parameter with index q = 0 is denoted, for example, as default parameter:

TABLE 10

Advantageous subset of adaptation parameters for set size 3

| q | Adaptation parameter pair |
|---|---|
| 0 | (1,4) |
| 1 | (0,1) |
| 2 | (2,6) |

For example, one parameter out of the subset is signaled, for example, by encoding q according to encoding scheme 1., where, for example, the bin useNotDefault is encoded using a context model and all other bins are encoded with a fixed length of one bit per bin.

In another embodiment (example), the configuration is identical to the previous advantageous embodiment, except for the assigned adaptation parameter pairs and the size of the chosen subset (Table 3), which is equal to 5.

TABLE 11

Advantageous subset of adaptation parameters for set size 5

| q | Adaptation parameter pair |
|---|---|
| 0 | (1,4) |
| 1 | (0,0) |
| 2 | (0,6) |
| 3 | (1,1) |
| 4 | (2,6) |

In another embodiment (example), the configuration is identical to the previous advantageous embodiment, except for assigned adaptation parameter pairs (Table 4):

TABLE 12

Second advantageous subset of adaptation parameters for set size 5

| q | Adaptation parameter pair |
|---|---|
| 0 | (1,2) |
| 1 | (0,0) |
| 2 | (0,5) |
| 3 | (2,5) |
| 4 | (3,4) |

In another embodiment (example), the configuration is identical to the previous advantageous embodiment, except for the assigned adaptation parameter pairs and the size of the chosen subset (Table 5), which is equal to 9.

TABLE 13

Advantageous subset of adaptation parameters for set size 9

| q | Adaptation parameter pair |
|---|---|
| 0 | (1,4) |
| 1 | (0,0) |
| 2 | (0,5) |
| 3 | (1,1) |
| 4 | (1,2) |
| 5 | (2,4) |
| 6 | (2,6) |
| 7 | (3,4) |
| 8 | (3,5) |

In another embodiment (example), the configuration is identical to the previous advantageous embodiment, except for the assigned adaptation parameter pairs (Table 6).

TABLE 14

Second advantageous subset of adaptation parameters for set size 9

| d | Adaptation parameter pair |
|---|---|
| 0 | (1,3) |
| 1 | (0,0) |
| 2 | (0,5) |
| 3 | (1,1) |
| 4 | (1,6) |
| 5 | (2,4) |
| 6 | (2,6) |
| 7 | (3,5) |
| 8 | (4,4) |

In another embodiment (example), the configuration is identical to the previous advantageous embodiment, except for assigned adaptation parameter pairs (Table 7), the size of the chosen subset (5), and the used quantization method, which uses URQ:

TABLE 15

Advantageous subset of adaptation parameters for set size 5 and URQ

| q | Adaptation parameter pair |
|---|---|
| 0 | (1,4) |
| 1 | (0,6) |
| 2 | (1,1) |
| 3 | (2,6) |
| 4 | (3,4) |

In another embodiment (example), an estimator is used, which is configured such that it is identical to the estimator used the current draft of MPEG-7 part 17 standard for compression of neural networks for multimedia content description and analysis and the base set of Table 1 is used. This is denoted as base configuration.

Whenever a layer parameter is quantized with DQ, the subset (of size 9) of parameter pairs in Table 5 is applied. If a layer parameter is quantized with URQ the subset in Table 8 is used.

TABLE 16

Advantageous subset of adaptation parameters for set size 9

| q | Adaptation parameter pair |
|---|---|
| 0 | (1,4) |
| 1 | (0,1) |
| 2 | (0,6) |
| 3 | (1,2) |
| 4 | (1,6) |
| 5 | (2,5) |
| 6 | (2,6) |
| 7 | (3,4) |
| 8 | (3,5) |

In another embodiment (example), the base configuration of the previous advantageous embodiment is applied.

Whenever the number of elements of a layer parameter is below a threshold X, which may for example be set to X = 1000, the subset with size 3 of parameter pairs, for example, in Table 2, denoted as first subset, is used. Otherwise, if the number of elements of a layer parameter is greater or equal to the threshold X, the subset with size 9, for example, in Table 5, denoted as second subset, is used.

In another embodiment (example), the configuration is identical to the previous advantageous embodiment, but instead of using a threshold, a flag (for example, useSecondSubset) is encoded, which determines, for example, the subset to be used. For example, if the flag is equal to zero, the first subset is used. If the flag is equal to one, the second subset is used.

Implementation alternatives:

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods may be performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

It should be noted that any embodiments as defined by the claims can be supplemented by any of the details (features and functionalities) described herein.

Also, the embodiments described herein can be used individually, and can also be supplemented by any of the features included in the claims.

Also, it should be noted that individual aspects described herein can be used individually or in combination. Thus, details can be added to each of said individual aspects without adding details to another one of said aspects.

It should also be noted that the present disclosure describes, in general, explicitly or implicitly, features usable in a video encoder (apparatus for providing an encoded representation of an input video signal) and in a video decoder (apparatus for providing a decoded representation of a video signal on the basis of an encoded representation), and in an audio encoder and in an audio decoder. Thus, any of the features described herein can be used in the context of a video encoder and in the context of a video decoder and in the context of an audio encoder and in the context of an audio decoder.

Moreover, features and functionalities disclosed herein relating to a method can also be used in an apparatus (configured to perform such functionality). Furthermore, any features and functionalities disclosed herein with respect to an apparatus can also be used in a corresponding method. In other words, the methods disclosed herein can be supplemented by any of the features and functionalities described with respect to the apparatuses.

Also, any of the features and functionalities described herein can be implemented in hardware or in software, or using a combination of hardware and software, as will be described in the section “implementation alternatives”.

Moreover, any of the features and syntax elements described herein can optionally be introduced into a video bit stream, both individually and taken in combination.

Furthermore, it should be noted that all features, functionalities and details described in the context of an encoder or of an encoding can optionally also be used in the context of a decoder or of a decoding. For example, a context derivation in a decoder may be analog to a context derivation in an encoder, wherein decoded valued may take the role of values to be encoded. Typically decoders are designed such that the context used in the decoder corresponds to the context used in the encoder, to keep the encoder and the decoder in synchronism.

While this invention has been described in terms of several embodiments, there are alterations, permutations, and equivalents which will be apparent to others skilled in the art and which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1-61. (canceled)

62. A decoder for decoding weight parameters of a neural network,
wherein the decoder is configured to acquire a plurality of neural network parameters of the neural network on the basis of an encoded bitstream;
wherein the decoder is configured to decode the neural network parameters of the neural network using a context-dependent arithmetic decoding;
wherein the decoder is configured to acquire a probability estimate for a decoding of a bin of a number representation of a neural network parameter using one or more probability estimation parameters;
wherein the decoder is configured to use different probability estimation parameter values for a decoding of different neural network parameters and/or to use different probability estimation parameter values for a decoding of bins associated with different context models.

63. A decoder for decoding weight parameters of a neural network,
wherein the decoder is configured to acquire a plurality of neural network parameters of the neural network on the basis of an encoded bitstream;
wherein the decoder is configured to decode the neural network parameters of the neural network using a context-dependent arithmetic decoding;
wherein the decoder is configured to acquire a probability estimate for a decoding of a bin of a number representation of a neural network parameter using one or more probability estimation parameters;
wherein the decoder is configured to use different probability estimation parameter values for a decoding of neural network parameters associated with different layers of the neural network.

64. The decoder according to claim 62,
wherein the decoder is configured to choose one or more probability estimation parameters from a base set,
or from a true subset of the base set.

65. The decoder according to claim 62,
wherein the decoder is configured to choose one or more probability estimation parameters from different sets of useable parameter values or of useable tuples of parameter values in dependence on a quantization mode and/or in dependence on a number of parameters of a layer of the neural network, or in dependence on a number of neural network parameters to be decoded using the chosen one or more probability estimation parameters, or in dependence on a number of elements of a layer parameter; or
wherein the decoder is configured to use different mapping rules mapping an encoded value representing one or more probability estimation parameters onto one or more probability estimation parameters in dependence on a quantization mode and/or in dependence on a number of parameters of a layer of the neural network, or in dependence on a number of neural network parameters to be decoded using the chosen one or more probability estimation parameters, or in dependence on a number of elements of a layer parameter.

66. The decoder according to claim 62,
wherein the decoder is configured to selectively choose one or more probability estimation parameters from a first set of useable parameter values or from a first set of useable tuples of parameter values
in case that a uniform quantization of the one or more probability estimation parameters is used, and/or
if the number of parameters of a layer of the neural network is below a threshold value or if the number of neural network parameters to be decoded using the chosen one or more probability estimation parameters is below a threshold value, or if the number of elements of the layer parameter is below a threshold value, and
wherein the decoder is configured to selectively choose one or more probability estimation parameters from a second set of useable parameter values or from a second set of useable tuples of parameter values
in case that a variable quantization of the one or more probability estimation parameters is used, and/or if the number of parameters of a layer of the neural network is above the threshold value or if the number of neural network parameters to be decoded using the chosen one or more probability estimation parameters is above the threshold value, or if the number of elements of the layer parameter is above the threshold value; or
wherein the decoder is configured to use, or to selectively use, a first mapping rule mapping an encoded value representing one or more probability estimation parameters onto one or more probability estimation parameters
in case that a uniform quantization of the one or more probability estimation parameters is used, and/or if the number of parameters of a layer of the neural network is below a threshold value or if the number of neural network parameters to be decoded using the chosen one or more probability estimation parameters is below a threshold value, or if the number of elements of the layer parameter is below a threshold value, and
wherein the decoder is configured to use, or to selectively use a second mapping rule mapping an encoded value representing one or more probability estimation parameters onto one or more probability estimation parameters
in case that a variable quantization of the one or more probability estimation parameters is used, and/or if the number of parameters of a layer of the neural network is above the threshold value or if the number of neural network parameters to be decoded using the chosen one or more probability estimation parameters is above the threshold value, or if the number of elements of the layer parameter is above the threshold value, and
wherein the first set of useable parameter values is different from the second set of useable parameter values, and
wherein the first set of useable tuples of parameter values is different from the second set of useable tuples of parameter values; and/or
wherein the second set of useable parameter values comprises more useable parameter values than the first set of useable parameter values, and wherein the second set of useable tuples of parameter values comprises more useable tuples than the first set of useable tuples of parameter values; and/or
wherein the second mapping rule is different from the first mapping rule.

67. The decoder according to claim 66,
wherein, on average, useable parameter values of the second set of useable parameter values allow for a faster adaptation of a probability estimate than useable parameter values of the first set of useable parameter values, or
wherein, on average, useable tuples of parameter values of the second set of useable tuples of parameter values allow for a faster adaptation of a probability estimate than useable tuples of parameter values of the first set of useable tuples of parameter values.

68. The decoder according to claim 66,
wherein the second set of useable parameter values comprises a useable parameter value which allows for a faster adaptation of a probability estimate than useable parameter values of the first set of useable parameter values, or
wherein the second set of useable tuples of parameter values comprises a useable tuple of parameter values which allows for a faster adaptation of a probability estimate than useable tuples of parameter values of the first set of useable tuples of parameter values.

69. The decoder according to claim 62,
wherein the decoder is configured to selectively choose the one or more probability estimation parameters from an increased choice if a number of neural network parameters to be decoded using the chosen one or more probability estimation parameters is larger than or equal to a threshold value.

70. The decoder according to claim 62,
wherein the decoder is configured evaluate a signaling from which set of useable parameter values or from which set of useable tuples of parameter values the one or more probability estimation parameters are elected; or
wherein the decoder is configured evaluate a signaling indication which mapping rule out of a plurality of mapping rules should be used to map an encoded value representing one or more probability estimation parameters onto one or more probability estimation parameters.

71. The decoder according to claim 62,
wherein the decoder is configured to decode one or more index values describing a probability estimation parameter value, or describing a plurality of probability estimation parameter values, or describing a tuple of probability estimation parameter values.

72. The decoder according to claim 71,
wherein the decoder is configured to decode the one or more index values using one or more context models.

73. The decoder according to claim 71,
wherein the decoder is configured to decode a first bin, which describes whether a currently considered index value takes a default value, and wherein the decoder is configured to selectively decode one or more additional bins representing the currently considered index value, or a value derived therefrom, in a binary representation, if the currently considered index value does not take the default value; or
wherein the decoder is configured to decode the one or more index values using a unary code decoding, or using a truncated unary code decoding, or using a variable length code decoding.

74. The decoder according to claim 62,
wherein the decoder is configured to vary a number of bins or a maximum number of bins used for decoding the one or more probability estimation parameters
in dependence on a quantization mode used for quantizing the one or more probability estimation parameters; and/or
in dependence on a number of parameters of a layer of the neural network, or in dependence on a number of neural network parameters to be decoded using the one or more probability estimation parameters, or in dependence on a number of elements of a layer parameter.

75. The decoder according to claim 62,
wherein the decoder is configured to switch between different sets of usable parameter values associated with the one or more probability estimation parameters, or between different sets of tuples of useable parameter values associated with a plurality of probability estimation parameters, or between different mapping rules for mapping an encoded value representing one or more probability estimation parameters onto one or more probability estimation parameters.

76. The decoder according to claim 75,
wherein the decoder is configured to vary a number of bins or a maximum number of bins used for decoding the one or more probability estimation parameters designating a selected probability estimation parameter or a selected tuple of probability estimation parameters in accordance with a switching between different sets of usable parameter values associated with the one or more probability estimation parameters, or between different sets of tuples of useable parameter values associated with a plurality of probability estimation parameters or between different mapping rules.

77. The decoder according to claim 62,
wherein the decoder is configured to determine one or more state variables and to derive the probability estimate using the one or more state variables.

78. The decoder according to claim 62,
wherein the decoder is configured to derive the probability estimate pₖ from two state variables _{S1}^{k}, _{S2}^{k} according to
$${s}_{k} = {\sum }_{i = 1}^{N} \left⌊{s}_{i}^{k} ⋅ {d}_{i}^{k}\right⌋$$
and
$${p}_{k} = \left\{\begin{matrix}L U T 2 \left[\left⌊{s}_{k} ⋅ {a}_{k}\right⌋\right] , \\ 1 - L U T 2 \left[- \left⌊{s}_{k} ⋅ {a}_{k}\right⌋\right] ,\end{matrix}\right) \begin{matrix}i f \left⌊{s}_{k} ⋅ {a}_{k}\right⌋ \geq 0. \\ e l s e\end{matrix}$$
.

79. The decoder according to claim 62,
wherein the decoder is configured to update the state variables _{S1}^{k}, _{S2}^{k} according to
$${s}_{i}^{k} = \left\{\begin{matrix}{s}_{i}^{k} + \left⌊A \left[z + \left⌊{s}_{i}^{k} ⋅ {m}_{i}^{k}\right⌋\right] ⋅ {n}_{i}^{k}\right⌋ , & I f d e c o d e d s y m b o l i s 1. \\ {s}_{i}^{k} + \left⌊A \left[z + \left⌊- {s}_{i}^{k} ⋅ {m}_{i}^{k}\right⌋\right] ⋅ {n}_{i}^{k}\right⌋ , & I f d e c o d e d s y m b o l i s 0.\end{matrix}\right)$$
wherein
$${m}_{i}^{k}$$
and
$${n}_{i}^{k}$$
are weighting factors; and
wherein A is a lookup table; and
wherein z is an offset value .

80. The decoder according to claim 79,
wherein the decoder is configured to vary the weighting factors
$${n}_{i}^{k} ,$$
so as to use different probability estimation parameter values for a decoding of different neural network parameters and/or to use different probability estimation parameter values for a decoding of bins associated with different context models and/or to use different probability estimation parameter values for a decoding of neural network parameters associated with different layers of the neural network.

81. The decoder according to claim 79,
wherein a relationship between the weighting factors
$${n}_{i}^{k}$$
and adaptation parameters
$$s {h}_{i}^{k}$$
is defined according to
$${n}_{i}^{k} = {2}^{- s {h}_{i}^{k} + 4}$$
.

82. An encoder for encoding weight parameters of a neural network,
wherein the encoder is configured to acquire a plurality of neural network parameters of the neural network;
wherein the encoder is configured to encode the neural network parameters of the neural network using a context-dependent arithmetic coding;
wherein the encoder is configured to acquire a probability estimate for an encoding of a bin of a number representation of a neural network parameter using one or more probability estimation parameters;
wherein the encoder is configured to use different probability estimation parameter values for an encoding of different neural network parameters and/or to use different probability estimation parameter values for an encoding of bins associated with different context models, or
wherein the encoder is configured to use different probability estimation parameter values for an encoding of neural network parameters associated with different layers of the neural network.

83. A method for decoding weight parameters of a neural network,
wherein the method comprises acquiring a plurality of neural network parameters of the neural network on the basis of an encoded bitstream;
wherein the method comprises decoding the neural network parameters of the neural network using a context-dependent arithmetic decoding;
wherein the method comprises acquiring a probability estimate for an decoding of a bin of a number representation of a neural network parameter using one or more probability estimation parameters;
wherein the method comprises using different probability estimation parameter values for a decoding of different neural network parameters and/or using different probability estimation parameter values for a decoding of bins associated with different context models or
wherein the method comprises using different probability estimation parameter values for a decoding of neural network parameters associated with different layers of the neural network.

84. A method for encoding weight parameters of a neural network,
wherein the method comprises acquiring a plurality of neural network parameters of the neural network;
wherein the method comprises encoding the neural network parameters of the neural network using a context-dependent arithmetic coding;
wherein the method comprises acquiring a probability estimate for an encoding of a bin of a number representation of a neural network parameter using one or more probability estimation parameters;
wherein the method comprises using different probability estimation parameter values for an encoding of different neural network parameters and/or using different probability estimation parameter values for an encoding of bins associated with different context models, or
wherein the method comprises using different probability estimation parameter values for an encoding of neural network parameters associated with different layers of the neural network.

85. A non-transitory digital storage medium having stored thereon a computer program for performing a method for decoding weight parameters of a neural network,
wherein the method comprises acquiring a plurality of neural network parameters of the neural network on the basis of an encoded bitstream;
wherein the method comprises decoding the neural network parameters of the neural network using a context-dependent arithmetic decoding;
wherein the method comprises acquiring a probability estimate for an decoding of a bin of a number representation of a neural network parameter using one or more probability estimation parameters;
wherein the method comprises using different probability estimation parameter values for a decoding of different neural network parameters and/or using different probability estimation parameter values for a decoding of bins associated with different context models or
wherein the method comprises using different probability estimation parameter values for a decoding of neural network parameters associated with different layers of the neural network,
when said computer program is run by a computer.

86. A non-transitory digital storage medium having stored thereon a computer program for performing a method for encoding weight parameters of a neural network,
wherein the method comprises acquiring a plurality of neural network parameters of the neural network;
wherein the method comprises encoding the neural network parameters of the neural network using a context-dependent arithmetic coding;
wherein the method comprises acquiring a probability estimate for an encoding of a bin of a number representation of a neural network parameter using one or more probability estimation parameters;
wherein the method comprises using different probability estimation parameter values for an encoding of different neural network parameters and/or using different probability estimation parameter values for an encoding of bins associated with different context models, or
wherein the method comprises using different probability estimation parameter values for an encoding of neural network parameters associated with different layers of the neural network,
when said computer program is run by a computer.

87. An encoded representation of weight parameters of a neural network, comprising:
a plurality of encoded weight parameters of the neural network; and
an encoded representation of one or more probability estimation parameters determining characteristics of a probability estimation for an adaptation of a context of an arithmetic decoding of the encoded weight parameters.
